(19) United States
(12) Patent Application Publication
(10) Pub. No.: US 2015/0376792 A1
(43) Pub. Date: Dec. 31, 2015

(54) ATMOSPHERIC PLASMA APPARATUS FOR SEMICONDUCTOR PROCESSING

(71) Applicant: Lam Research Corporation, Fremont, CA (US)

(72) Inventors: Tighe A. Spurlin, Portland, OR (US); George Andrew Antonelli, Portland, OR (US); Jonathan D. Reid, Sherwood, OR (US); David Porter, Sherwood, OR (US)

(21) Appl. No.: 14/320,171

(22) Filed: Jun. 30, 2014

(51) Int. Cl. C23C 16/50; C25D 5/34; H01L 21/768; C25D 7/12; C23C 16/453; C23C 16/52

(52) U.S. Cl. CPC C23C 16/50; C23C 16/453; C23C 16/52; H01L 21/76826; C25D 7/12; C25D 5/34

(57) ABSTRACT

Method and apparatus for treating a substrate prior to deposition using atmospheric plasma are disclosed. A substrate can be provided between a substrate support and a plasma distributor, where the plasma distributor includes one or more atmospheric plasma sources. The atmospheric plasma sources can generate plasma under atmospheric pressure, where the plasma can include radicals and ions of a process gas, such as a reducing gas species. The substrate can be exposed to the plasma under atmospheric pressure to treat the surface of the substrate, where atmospheric pressure can be between about 50 Torr and about 760 Torr. In some embodiments, substrate includes a metal seed layer having portions converted to oxide of a metal, where exposure to the plasma reduces the oxide of the metal and reflows the metal in the metal seed layer.

### INTRODUCTION

### Field of the Invention

This disclosure generally relates to treating substrates prior to deposition using atmospheric plasma. Certain aspects of this disclosure pertain to an apparatus for treating surfaces of one or more substrates to reduce metal oxides with plasma under atmospheric pressure.

### BACKGROUND

Various processes in semiconductor device manufacturing commonly require pretreatment, cleaning, or processing of substrates prior to deposition of material on the surface of the substrates. In some instances, metal oxides and carbon deposits, as well as potentially other contaminants, may form on a substrate surface that may present challenges to deposition of subsequent layers. Therefore, various pretreatment processes may be used to remove metal oxides and other contaminants. In addition, a metal surface such as a tungsten surface may require cleaning before deposition of a subsequent layer, such as a hard mask layer.

An example of treating or otherwise processing a substrate prior to deposition can be reducing metal oxides on a metal seed layer or semi-noble metal layer. Formation of metal wiring interconnects in integrated circuits (ICs) can be achieved using a damascene or dual damascene process. Typically, trenches or holes are etched into dielectric material, such as silicon dioxide, located on a substrate. The holes or trenches may be lined with one or more adhesion and/or diffusion barrier layers. Then a thin layer of metal may be deposited in the holes or trenches that can act as a seed layer for electroplated metal. Thereafter, the holes or trenches may be filled with electroplated metal. Typically, the seed metal is copper. However, other metals such as ruthenium, palladium, iridium, rhodium, osmium, cobalt, nickel, gold, silver, and aluminum, or alloys of these metals, may also be used. To achieve higher performance ICs, many of the features of the ICs are being fabricated with smaller feature sizes and higher densities of components. In some damascene processing, for example, copper seed layers on 2X-nm node features may be as thin as or thinner than 50 Å. In some implementations, metal seed layers on 1X-nm node features may be applied that may or may not include copper. Technical challenges arise with smaller feature sizes in producing metal seed layers and metal interconnects substantially free of voids or defects.

Various processes in semiconductor manufacturing can also require processing of substrates to affect the physical, electrical, chemical, mechanical, adhesive, or thermal properties of one or more layers deposited on the substrate. For example, the presence of hydrogen and carbon atoms in a low-k dielectric material can degrade the low-k dielectric material.

Typically, substrates in a semiconductor manufacturing process can be treated or otherwise processed using plasma. The plasma may be very effective in cleaning substrate surfaces, especially in removing metal oxides, hydrocarbons, and other contaminants. However, the plasma, including direct plasma and remote plasma, is generated and delivered in a low pressure system that can require additional assembly for load lock operation and vacuum pumping. Such assemblies may increase the cost of operation and maintenance. Moreover, the additional assemblies may occupy an increased amount of space (e.g., floor space). Additional assemblies also may reduce the throughput of the substrate processing.

### SUMMARY

This disclosure pertains to methods of treating a substrate prior to deposition using atmospheric plasma. The method can include providing a substrate between a substrate support and one or more atmospheric plasma sources, providing a process gas to the one or more atmospheric plasma sources, forming a plasma under atmospheric pressure in the one or more atmospheric plasma sources, and exposing the substrate to the plasma under atmospheric pressure to treat the surface of the substrate. The plasma includes radicals and ions of the process gas. Atmospheric pressure can be between about 50 Torr and about 760 Torr.

In some embodiments, providing the substrate includes providing the substrate at a distance between about 0.1 mm and about 10 mm from the one or more atmospheric plasma sources. In some embodiments, providing the substrate includes providing the substrate with a metal seed layer formed thereon, a portion of the metal seed layer having been converted to oxide of the metal, and where exposing the substrate to the plasma includes exposing the metal seed layer of the substrate to the plasma under conditions that reduce the oxide of the metal and reflow the metal in the metal seed layer. In some embodiments, the method can further include transferring the substrate to a plating bath containing a plating solution after exposing the substrate to the plasma. In some embodiments, the plasma includes radicals and ions of a reducing gas species including at least one of hydrogen and ammonia.

This disclosure also pertains to an apparatus for treating a substrate prior to deposition using atmospheric plasma. The apparatus includes a substrate support for supporting the substrate, a plasma distributor over the substrate support for delivering plasma to the surface of the substrate, where the plasma distributor includes one or more atmospheric plasma sources configured to generate the plasma, and a controller with instructions for performing the following operations: (a) providing the substrate between the substrate support and the plasma distributor, (b) forming the plasma under atmospheric pressure, and (c) exposing the substrate to the plasma under atmospheric pressure to treat the surface of the substrate, where atmospheric pressure is between about 50 Torr and about 760 Torr.

In some embodiments, the substrate support and the plasma distributor are configured to provide the substrate at a distance between about 0.1 mm and about 10 mm from the plasma distributor during operations (a)-(c). In some embodiments, operation (a) includes providing the substrate with a metal seed layer formed thereon, a portion of the metal seed layer having been converted to oxide of the metal, and where operation (c) includes exposing the metal seed layer of the substrate to the plasma under conditions that reduce the oxide of the metal and reflow the metal in the metal seed layer. The metal seed layer can include a copper seed layer having a thickness between about 40 Å and about 80 Å. In some embodiments, the controller further includes instructions for transferring the substrate to a plating bath containing a plating solution after exposing the substrate to the plasma. In some embodiments, the one or more atmospheric plasma sources include a plurality of plasma jets. In some embodiments, the plasma distributor includes a ceramic body and a metal electrode below the ceramic body. In some embodiments, the apparatus further includes a showerhead disposed between the plasma distributor and the substrate, where the showerhead includes a plurality of holes.

### BRIEF DESCRIPTION OF THE DRAWINGS

FIG. 1A shows an example of a cross-sectional schematic of dielectric layers prior to a via etch in a damascene process.

FIG. 1B shows an example of a cross-sectional schematic of the dielectric layers in FIG. 1A after an etch has been performed in the damascene process.

FIG. 1C shows an example of a cross-sectional schematic of the dielectric layers in FIGS. 1A and 1B after the etched regions have been filled with metal in the damascene process.

FIG. 2A shows an exemplary flow diagram illustrating a method of treating a substrate with a metal seed layer for plating copper on the substrate.

FIG. 2B shows an exemplary flow diagram illustrating a method of treating a substrate with a metal seed layer or semi-noble metal layer for plating metal on the substrate.

FIG. 3A shows an exemplary flow diagram illustrating a method of treating a substrate using atmospheric plasma.

FIG. 3B shows an exemplary flow diagram illustrating a method of treating a substrate using atmospheric plasma to reduce metal oxides prior to plating metal on the substrate.

FIG. 4A shows an example of a cross-sectional schematic of an oxidized metal layer.

FIG. 4B shows an example of a cross-sectional schematic of a metal layer with a void due to removal of metal oxide.

FIG. 4C shows an example of a cross-sectional schematic of a metal layer with reduced metal oxide forming a reaction product not integrated with the metal layer.

FIG. 4D shows an example of a cross-sectional schematic of a metal layer with reduced metal oxide forming a film integrated with the metal layer.

FIG. 5A shows an example of a top view schematic of an electroplating apparatus.

FIG. 5B shows an example of a top view schematic of an electroplating apparatus with a remote plasma apparatus.

FIG. 5C shows an example of a block diagram of an electroplating apparatus for a low pressure system.

FIG. 5D shows an example of a block diagram of an electroplating apparatus for a high pressure system in some implementations.

FIG. 5E shows an example of a block diagram of an electroplating apparatus for a high pressure system in some implementations.

FIG. 6A shows an example of a cross-sectional schematic diagram of a remote plasma apparatus.

FIG. 6B shows an example of a cross-sectional schematic diagram of a direct atmospheric plasma apparatus.

FIG. 6C shows an example of a cross-sectional schematic diagram of a remote atmospheric plasma apparatus.

FIG. 6D shows an example of a cross-sectional schematic diagram of an atmospheric plasma apparatus using a hollow cathode discharge.

FIG. 7A shows an example of a cross-sectional schematic diagram of a two-chamber atmospheric plasma apparatus.

FIG. 7B shows an example of a cross-sectional schematic diagram of a plurality of stacked two-chamber atmospheric plasma apparatuses.

### DETAILED DESCRIPTION

In the following description, numerous specific details are set forth in order to provide a thorough understanding of the presented concepts. The presented concepts may be practiced without some or all of these specific details. In other instances, well known process operations have not been described in detail so as to not unnecessarily obscure the described concepts. While some concepts will be described in conjunction with the specific embodiments, it will be understood that these embodiments are not intended to be limiting.

### Introduction

In this disclosure, various terms are used to describe a semiconductor processing work surface, and “wafer” and “substrate” are used interchangeably. The process of depositing, or plating, metal onto a conductive surface via an electrochemical reaction can be referred to generally as electroplating or electrofilling. Bulk electrofilling refers to electroplating a relatively large amount of copper to fill trenches and vias.

Although the present disclosure may be used in a variety of applications, one useful application is the damascene or dual damascene process commonly used in the manufacture of semiconductor devices. The damascene or dual damascene processes may include metal interconnects, such as copper interconnects.

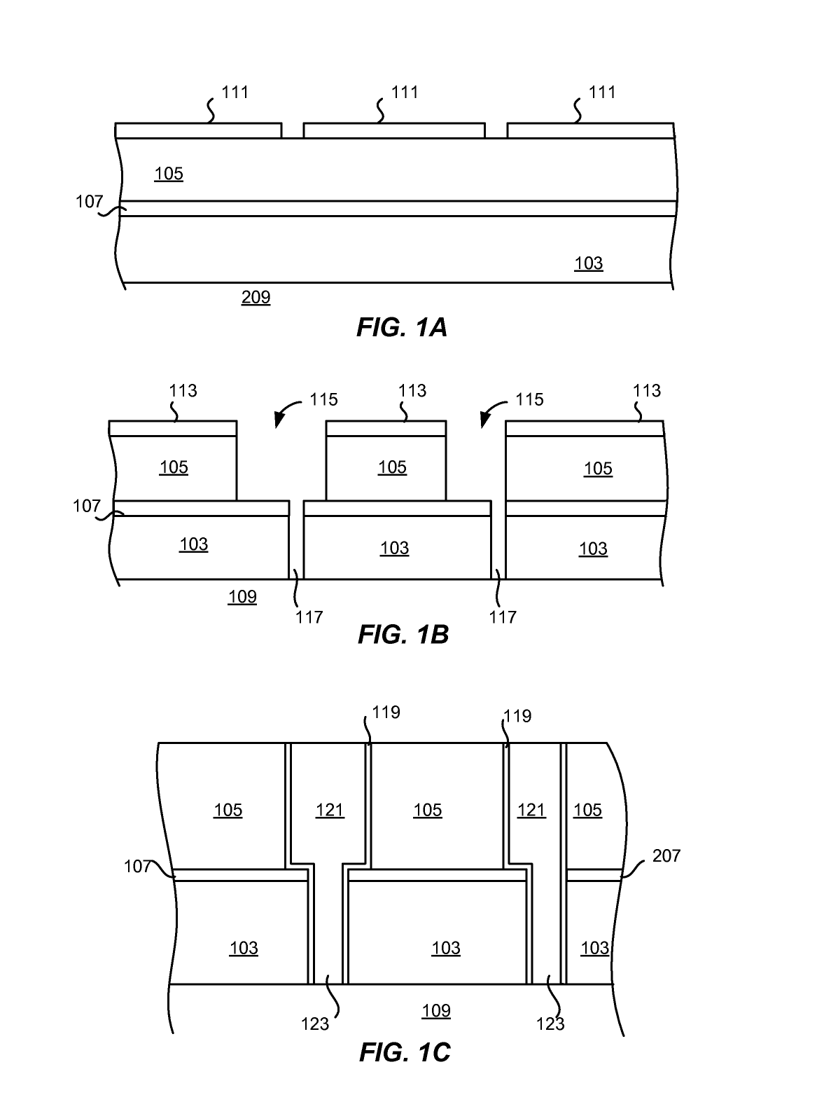

A generalized version of a dual damascene technique may be described with reference to FIGS. 1A-1C, which depicts some of the stages of the dual damascene process.

FIG. 1A shows an example of a cross-sectional schematic of one or more dielectric layers prior to a via etch in a damascene process. In a dual damascene process, first and second layers of dielectric are normally deposited in succession, possibly separated by deposition of an etch stop layer, such as a silicon nitride layer. These layers are depicted in FIG. 1A as a first dielectric layer 103, second dielectric layer 105, and etch stop layer 107. These are formed on an adjacent portion of a substrate 109, which a portion may be an underlying metallization layer or a gate electrode layer (at the device level).

After deposition of the second dielectric layer 105, the process forms a via mask 111 having openings where vias will be subsequently etched. FIG. 1B shows an example of a cross-sectional schematic of the one or more dielectric layers in FIG. 1A after an etch has been performed in the damascene process. Next, vias are partially etched down through the level of etch stop 107. Then via mask 111 is stripped off and replaced with a line mask 113 as depicted in FIG. 1B. A second etch operation is performed to remove sufficient amounts of dielectric to define line paths 115 in second dielectric layer 105. The etch operation also extends via holes 117 through first dielectric layer 103, down to contact the underlying substrate 109 as illustrated in FIG. 1B.

Thereafter, the process forms a thin layer of relatively conductive barrier layer material 119 on the exposed surfaces (including sidewalls) of dielectric layers 103 and 105. FIG. 1C shows an example of a cross-sectional schematic of the dielectric layers in FIGS. 1A and 1B after the etched regions have been coated with a conductive barrier layer material and filled with metal in the damascene process. Conductive barrier layer material 119 may be formed, for example, of tantalum nitride (TaN) or titanium nitride (TiN). A chemical vapor deposition (CVD), an atomic layer deposition (ALD), or a physical vapor deposition (PVD) operation is typically employed to deposit the conductive barrier layer material 119.

On top of the conductive barrier layer material 119, the process then deposits conductive metal 121 (typically, though not necessarily, copper) in the via holes and line paths 117 and 115. Conventionally this deposition is performed in two steps: an initial deposition of a metal seed layer followed by bulk deposition of metal by plating. However, the present disclosure provides a pre-treatment step prior to the bulk deposition step, as described in detail below. The metal seed layer may be deposited by PVD, CVD, electroless plating, or any other suitable deposition technique known in the art. Note that the bulk deposition of copper not only fills line paths 115 but, to ensure complete filling, covers all the exposed regions on top of second dielectric layer 105. The metal 121 may serve as copper interconnects for IC devices. In some embodiments, metals other than copper are used in the seed layer. Examples of such other metals include cobalt, tungsten, and ruthenium.

Metal seed layers, including the semi-noble metal layers, can readily react with oxygen or water vapor in the air and oxidize from a pure metal into a mixed film of a metal oxide and a buried pure metal. While the oxidation under ambient conditions may be limited to a thin surface layer of some metals, that thin layer may represent a significant fraction or perhaps the entire thickness of thin seed layers used in current technology nodes. The relatively thin layers may be necessitated by the technology node, such as the 4x nm node, the 3x nm node, the 2x nm node, and the 1x nm node, and less than 10 nm. The height to width aspect ratio of vias and trenches in technology nodes necessitating relatively thin metal layers can be about 5:1 or greater. In such technology nodes, the thickness of the metal seed layer can be less than about 100 Å on average as a result. In some implementations, the thickness of the metal seed layer can be less than about 50 Å on average.

Through the general chemical reactions shown in Equation 1 and Equation 2 below, metals used for seed layers and semi-noble metal layers are converted to metal oxides (Mox), though the exact reaction mechanisms between the metal surfaces (M) and ambient oxygen or water vapor can vary depending on the properties and the oxidation state.

2M₍ₛ₎+O_{2(g)}→2MOx₍ₛ₎ Equation 1

2M₍ₛ₎+H₂O_{(g)}→M₂Ox+H_{2(g)} Equation 2

For example, copper seed deposited on substrates is known to rapidly form copper oxide upon exposure to the air. A copper oxide film can form a layer that is approximately 20 Å and upwards to 50 Å thick on top of underlying copper metal. Moreover, cobalt layers deposited on substrates are known to rapidly form cobalt oxide. A cobalt oxide film can form a layer on top of the underlying cobalt metal that can covert upwards of 70%, 80%, 90%, and 98% of the cobalt metal to cobalt oxide. As metal seed layers become thinner and thinner, the formation of metal oxides from oxidation in ambient conditions can pose significant technical challenges.

Conversion of pure metal seed to metal oxide can lead to several problems. This is true not only in current copper damascene processing, but also for electrodeposition processes that use different conductive metals, such as ruthenium, cobalt, silver, aluminum, and alloys of these metals. First, an oxidized surface is difficult to plate on. Due to different interactions that electroplating bath additives can have on metal oxide and pure metal, non-uniform plating may result. As a result of the differences in conductivity between a metal oxide and a pure metal, non-uniform plating may further result. Second, voids may form in the metal seed that may make portions of the metal seed unavailable to support plating. The voids may form as a result of dissolution of metal oxide during exposure to corrosive plating solutions. The voids also may form on the surface due to non-uniform plating. Additionally, plating bulk metal on top of an oxidized surface can lead to adhesion or delamination problems, which can further lead to voids following subsequent processing steps, such as chemical mechanical planarization (CMP). Voids that result from etching, non-uniform plating, delamination, or other means may make the metal seed layer discontinuous, and unavailable to support plating. In fact, because modern damascene metal seed layers are relatively thin, such as about 50 Å or thinner, even a little oxidation may consume an entire layer thickness. Third, metal oxide formation may impede post-electrodeposition steps, such as capping, where the metal oxide may limit adhesion for capping layers.

The aforementioned issues may also occur for plating metal seed layers on semi-noble metal layers. Substrates with a semi-noble metal layer, such as a cobalt layer, may have significant portions of the semi-noble metal layer converted to oxide. Plating a metal seed layer, such as a copper seed layer, on the semi-noble metal layer can lead to void formation, pitting, non-uniform plating, and adhesion/delamination problems.

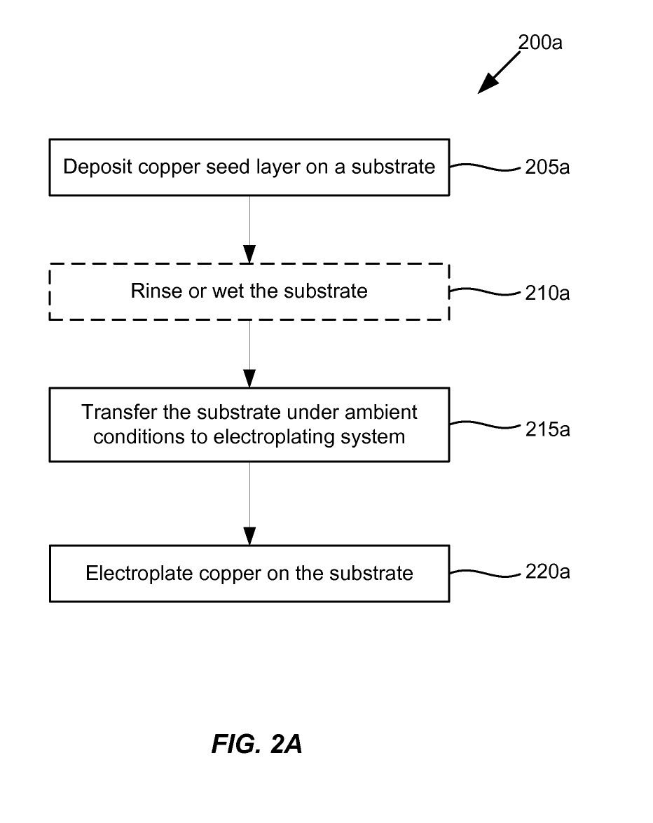

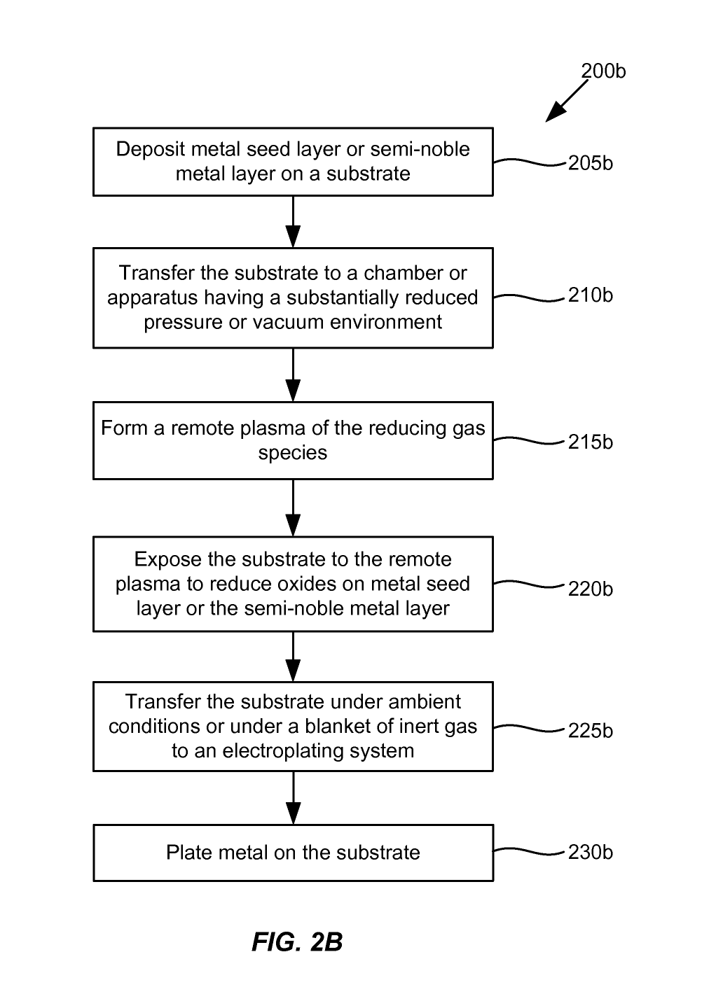

FIG. 2A shows an exemplary flow diagram illustrating a method of treating a substrate with a metal seed layer for plating copper on the substrate. The process 200a may begin at step 205a, where a process chamber or deposition chamber receives a substrate such as a semiconductor substrate. A metal seed layer such as a copper seed layer may be deposited on the substrate using a suitable deposition technique such as PVD. The seed layer may have an average thickness of about 15 Å to about 100 Å or larger. In some embodiments, the seed layer can have a thickness between about 40 Å and about 80 Å. The substrate may include feature having sidewalls and bottoms. The features may be a dielectric material with trenches and vias etched therein for depositing of liner/barrier layer and copper interconnect. The features may also include some liner/barrier layer material. For example a layer of titanium (Ti), tantalum (Ta), tantalum nitride (TaN), tantalum nitride silicon (TaNSi), tungsten (W), titanium nitride (TiN), or titanium nitride silicon (TiNSi) may be deposited first. The features are commonly trenches and vias for forming copper interconnects in a damascene process. In some embodiments, the features may have depths of about 15 nm to 100 nm and may have openings with a dimension of about 10 nm to about 30 nm before the semi-noble metal layer and the copper seed layer are deposited. In some embodiments, the features have a height to width aspect ratio of greater than about 5:1, such as greater than about 10:1.

At optional step 210a, the substrate may be rinsed and dried. For example, the metal seed layer may be rinsed with de-ionized water. The rinsing step may be limited to a time, for example, of between about 1 and 10 seconds, but may take a longer or shorter time. Subsequently, the substrate may be dried, which can be between about 20 and 40 seconds, though the drying step may take a longer or shorter time.

At step 215a, the substrate is transferred to the electroplating system or bath. During the transfer, the copper seed layer may be exposed to ambient conditions such that the copper seed layer may rapidly oxidize. In some embodiments, the duration of this exposure may be anywhere between about 1 minute and about 4 hours, between about 15 minutes and about 1 hour, or more. At step 220a, a bulk layer of copper may be electroplated on the substrate. The substrate with the copper seed layer can be, for example, immersed in an electroplating bath containing positive ions of copper and associated anions in an acid solution. At the plating bath, a bulk layer of copper is electroplated onto the substrate to fill the features. A conventional electroplating chemistry and waveform may be used. In some embodiments, step 220a of FIG. 2A can involve a series of processes that is described in U.S. Pat. No. 6,793,796, filed Feb. 27, 2001 (attorney docket no. NOVLP073), the entirety of which is hereby incorporated by reference. The reference describes at least four phases of the electrofilling process and discloses controlled current density methods for each phase for optimal filling of relatively small embedded features.

With various steps that may expose the metal seed layer to oxidation between deposition of the metal seed layer and electroplating, a technique for reducing the negative effects of the metal oxide surfaces is needed. However, some of the current techniques may have drawbacks. Typically, the use of hydrogen-based plasmas may reduce thick metal oxides, but such techniques add substantial costs and utilize substantially high temperatures (e.g., at least over 200° C.) that can badly damage a thin metal seed layer resulting in high void counts within features. A thermal forming gas anneal to reduce thick metal oxides uses a forming gas (e.g., mixture of hydrogen and nitrogen gas) at temperatures higher than 150° C., which can cause metal seed to agglomerate and also lead to increased voiding. The use of acids or other chemical reagents may dissolve or etch thick metal oxides, but removal of such oxides results in increased void formation in regions where metal cannot be plated on, due to the creation of regions with insufficient seed layer where metal cannot be plated on.

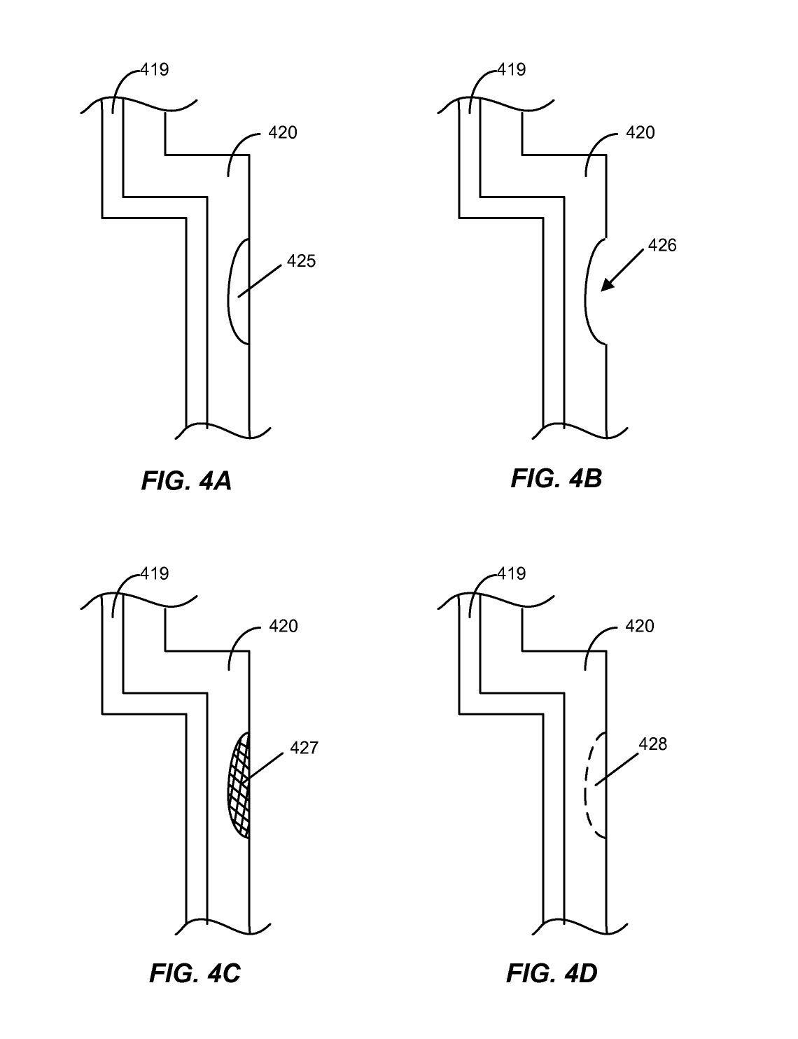

FIG. 2B shows an exemplary flow diagram illustrating a method of treating a substrate with a metal seed layer or semi-noble metal layer for plating metal on the substrate. The process 200b may be described with reference to some examples as illustrated in FIGS. 4A-4D. The process can begin with step 205b where a metal seed layer or semi-noble metal layer is deposited on the substrate. The metal seed layer can be a copper seed layer. The semi-noble metal layer can be a cobalt layer or ruthenium layer. The substrate may have recesses, vias, or trenches having height to width aspect ratios of greater than about 3:1 or greater than about 5:1.

The process 200b can continue with step 210b where the substrate is transferred to a chamber or apparatus having a substantially reduced pressure or vacuum environment. A reduced pressure or vacuum environment can have a pressure between about 0.1 Torr and about 5 Torr. The chamber or apparatus can include a reducing gas species, such as hydrogen (H₂), ammonia (NH₃), carbon monoxide (CO), diborane (B₂H₆), sulfite compounds, carbon and/or hydrocarbons, phosphites, and/or hydrazine (N₂H₄). During the transfer in step 210b, the substrate may be exposed to ambient conditions that can cause the surface of the metal seed layer or semi-noble metal layer to oxidize. Thus, at least a portion of the metal may be converted to an oxidized metal.

At step 215b, while the substrate is in the reduced or vacuum environment, a remote plasma may be formed of the reducing gas species. The remote plasma may include radicals of the reducing gas species, such as, for example, H*, NH₂*, or N₂H₃*. The radicals of the reducing gas species react with the metal oxide surface to generate a pure metallic surface. As demonstrated below, Equation 3 shows an example a reducing gas species such as hydrogen gas being broken down into hydrogen radicals. Equation 4 shows the hydrogen radicals reacting with the metal oxide surface to convert the metal oxide to metal. For hydrogen gas molecules that are not broken down or hydrogen radicals that recombine to form hydrogen gas molecules, the hydrogen gas molecules can still serve as a reducing agent for converting the metal oxide to metal, as shown in Equation 5.

H₂→2H* Equation 3

(x)2H*+MOx→M+(x)H₂O Equation 4

xH₂+MOx→M+xH₂O Equation 5

The radicals of the reducing gas species, ions from the reducing gas species, ultraviolet (UV) radiation from the reducing gas species, or the reducing gas species itself reacts with the metal oxide under conditions that convert the metal oxide to metal in the form of a film integrated with the metal seed layer or semi-noble metal layer, as shown in step 220b. Characteristics of the film integrated with the metal seed layer or semi-noble metal layer are discussed in further detail with respect to FIG. 4D below.

At step 220b, the substrate is exposed to the remote plasma to reduce oxides of the metal seed layer or the semi-noble metal layer. The remote plasma may include ions and other charged species of the reducing gas species. The ions and charged species of the reducing gas species may move to the surface of the substrate to react or otherwise contact the metal seed layer or semi-noble metal layer. The ions or charged species may freely drift toward the surface of the substrate or be accelerated toward the surface of the substrate when an oppositely charged bias is provided on a substrate support. The ions or charged species may react with the metal oxide to reduce the metal oxide. In some implementations, the ions or charged species in the remote plasma can include, for example, H⁺, NH₂⁺, NH₃⁺, and H⁻. Ions or charged species may be advantageous for reducing oxide on metal seed layers and semi-noble metal layers depending on a thickness and nature of the oxide layers, which can form on copper, cobalt, ruthenium, palladium, rhodium, iridium, osmium, nickel, gold, silver, aluminum, tungsten, and alloys thereof. For example, the ions or charged species may be beneficial for treatment of a layer containing cobalt.

The remote plasma also may generate and include UV radiation from the reducing gas species. Excitation of the reducing gas molecules from the remote plasma may cause emission of photons. The emitted photons may lead to one of several effects. First, the emitted photons in the UV spectrum may heat the surface of the substrate to activate the metal oxide surface so that radicals, ions, and other charged species can more readily react with the metal oxide surface. Second, reducing gas species may absorb the emitted photons and generate radicals of the reducing gas species. The generated radicals may react with the metal oxide surface to reduce the metal oxide. Third, the emitted photon may have sufficient energy to cause reduction of the metal oxide itself.

The energy of the remote plasma may be increased to generate higher energy species, including higher energy ions. Higher energy ions may be produced in high density plasma (HDP) processing systems and/or sputtering systems. Also, when the remote plasma generates UV radiation as a result of excitation of the reducing gas species, the generated UV radiation can have a wavelength between about 100 nm and about 700 nm. For example, the generated UV radiation can include short wavelength UV light, such as between about 120 nm and about 200 nm, and long wavelength UV light, such as between about 200 nm and about 700 nm. In addition, the remote plasma may include neutrals and/or generate recombined molecules of the reducing gas species. When the oxide of the metal is exposed to the remote plasma, the exposure reduces the oxide of the metal and reflows the metal in the metal layer. In some implementations, reflow of the metal and the reduction of the metal oxide may occur concurrently. In some implementations, the remote plasma can include radicals, ions, and UV radiation from the reducing gas species, or some combination thereof. A showerhead between the remote plasma source and the processing chamber can have a thickness, a number of holes, and an average diameter of holes configured to permit radicals, ions, and UV radiation flow or otherwise travel through the showerhead toward the substrate. The radicals, ions, and UV radiation may enter the processing chamber and reduce metal oxide in the metal seed layer or semi-noble metal layer. High energy ions may penetrate further from the surface of the substrate to provide a reducing chemistry throughout more of the metal seed layer or semi-noble metal layer. UV radiation may activate the metal oxide surface to improve the thermodynamics of the reduction process, or directly reduce the metal oxide itself. The UV radiation may also be absorbed by the reducing gas species and give rise to radicals that can reduce metal oxide. Furthermore, neutral molecules of the reducing gas species may further react and reduce metal oxide in the metal seed layer or semi-noble metal layer.

In some embodiments, the metal in the metal seed layer or semi-noble metal layer may be excited and mobilized upon exposure. The metal may be reflowed to reduce gaps and voids in the metal seed layer or semi-noble metal layer, which can reduce the surface roughness of the metal seed layer or semi-noble metal layer. How much the metal is reflowed can depend on the temperature of the substrate, the chamber pressure, the reducing gas species, and the intensity of the UV radiation, for example. As the metal is reflowed and redistributed on the underlying layer, a more uniform and continuous metal seed layer or semi-noble metal layer can be formed.

In some implementations, the remote plasma may not only reduce metal oxide to metal for more uniform plating, the remote plasma may also increase the conductivity of the metal seed layer or semi-noble metal layer by removing organic impurities left behind from the as-deposited metal layer. For example, the remote plasma may remove organic impurities left behind from CVD-deposited cobalt layers.

The process conditions for converting the metal oxide to metal in the form of a film integrated with the metal seed layer or semi-noble metal layer can vary depending on the choice of metal and/or on the choice of the reducing gas species. In some embodiments, the reducing gas species can include at least one of H₂, NH₃, CO, carbon and/or hydrocarbons, B₂H₆, sulfite compounds, phosphites, and N₂H₄. In addition, the reducing gas species can be combined with mixing gas species, such as relatively inert gas species. Examples of relatively inert gas species can include nitrogen (N₂), helium (He), neon (Ne), krypton (Kr), xenon (Xe), radon (Rn), and argon (Ar). The flow rate of the reducing gas species can vary depending on the size of the substrate for processing. For example, the flow rate of the reducing gas species can be between about 10 standard cubic centimeter per minute (sccm) and about 100,000 sccm for processing a single 450 mm substrate. Other wafer sizes can also apply. For example, the flow rate of the reducing gas species can be between about 500 sccm and about 30,000 sccm for processing a single 300 mm substrate.

Processing conditions such as temperature and pressure in the reducing chamber can also be controlled to permit conversion of the metal oxide to metal in the form of a film integrated with the metal seed layer or semi-noble metal layer. In some embodiments, the temperature of the reducing chamber can be relatively high to permit the dissociation of reducing gas species into radicals. For example, the reducing chamber can be anywhere between about 10° C. and about 500° C., such as between about 50° C. and about 250° C. Higher temperatures may be used to speed up metal oxide reduction reactions and shorten the duration of exposure to the reducing gas atmosphere (e.g., plasma treatment). In some embodiments, the reducing chamber can have a relatively low pressure to substantially remove any oxygen from the reducing gas atmosphere, as minimizing the presence of oxygen in the atmosphere can reduce the effects of reoxidation. For example, the reducing chamber can be pumped down to a vacuum environment or a reduced pressure of between about 0.1 Torr and about 5 Torr. The increased temperature and/or the reduced temperature can also increase reflow of metal atoms in the metal seed layer or semi-noble metal layer to create a more uniform and continuous layer.

Although the reducing chamber can have a relatively high temperature to permit the dissociation of reducing gas species into radicals, the temperature of the substrate itself may be separately controlled to avoid or reduce damage to the metal seed layer. Depending on the type of metal in the metal seed layer, the metal can begin to agglomerate above a threshold temperature. The effects of agglomeration are more pronounced in relatively thin seed layers, especially in seed layers having a thickness less than about 100 Å. Agglomeration includes any coalescing or beading of a continuous or semi-continuous metal seed layer into beads, bumps, islands, or other masses to form a discontinuous metal seed layer. This can cause the metal seed layer to peel away from the surface upon which it is disposed and can lead to increased voiding during plating. For example, the temperature at which agglomeration begins to occur in copper is greater than about 100° C. Different agglomeration temperatures may be appropriate for different metals.

To control the temperature of the substrate and minimize the effects of agglomeration, a cooling system such as an actively cooled pedestal and/or gas flow cooling apparatus in the reducing chamber can be used to keep the local area of the substrate at temperatures below the agglomeration temperature. In some embodiments, the substrate may be supported upon and directly in contact with the pedestal. In some embodiments, a gap may exist between the pedestal and the substrate. Heat transfer can occur via conduction, convection, radiation, or combinations thereof.

In some implementations, an actively cooled pedestal provides a heat transfer element with resistive heating elements, cooling channels, or other heat sources or sinks embedded within the pedestal. For example, the pedestal can include cooling elements that permit a fluid such as water to circulate within the pedestal and actively cool the pedestal. In some embodiments, the cooling elements can be located outside the pedestal. In some embodiments, the cooling fluid can include a low-boiling fluid, such as glycols. Embodiments that include such cooling elements can be described in U.S. Pat. No. 7,327,948 (attorney docket no. NOVLP127X1), issued Feb. 5, 2008; U.S. Pat. No. 7,941,039 (attorney docket no. NOVLP127X3), issued Jan. 5, 2011; U.S. patent application Ser. No. 11/751,584 (attorney docket no. NOVLP127X2), filed May 21, 2007; U.S. patent application Ser. No. 13/370,579 (attorney docket no. NOVLP127C1), filed Feb. 10, 2012; and U.S. Pat. No. 8,137,465 (attorney docket no. NOVLP127), issued Mar. 20, 2012, each of which are incorporated herein by reference in its entirety and for all purposes. Temperature in the pedestal can be actively controlled using a feedback loop.

In some implementations, a gap can exist between the pedestal and the substrate, and a conductive media such as gas can be introduced between the pedestal and the substrate to cool the substrate. In some embodiments, the conductive media can include helium. In some embodiments, the pedestal can be convex or concave to promote uniform cooling across the substrate. Examples of pedestal profiles can be described in U.S. patent application Ser. No. 11/129,266 (attorney docket no. NOVLP361), filed May 12, 2005; U.S. patent application Ser. No. 11/546,189 (attorney docket no. NOVLP198), filed Oct. 10, 2006; and U.S. patent application Ser. No. 12/749,170 (attorney docket no. NOVLP361D1), filed Mar. 29, 2010, each of which is incorporated herein by reference in its entirety and for all purposes.

Different configurations can be utilized to efficiently cool and to maintain a substantially uniform temperature across the substrate. Some implementations of an active cooling system include a pedestal circulating water within the pedestal coupled with a uniform gas flow across the substrate. Other implementations include a pedestal resistively heated and coupled with a uniform gas flow across the substrate. Other configurations and/or additions may also be provided with the active cooling system. For example, a removable ceramic cover can be inserted between the pedestal and the substrate to promote substantially uniform temperature across the substrate, as described in U.S. patent application Ser. No. 13/086,010 (attorney docket no. NOVLP400), filed Apr. 13, 2011, which is incorporated herein by reference in its entirety and for all purposes. In some embodiments, gas flow can be controlled with minimum contact supports to rapidly and uniformly cool the substrate, as described in U.S. Pat. No. 8,033,771 (attorney docket no. NOVLP298), issued Oct. 11, 2011, which is incorporated herein by reference in its entirety and for all purposes. In some embodiments, the heat transfer coefficient of the conductive media can be adjusted by varying the partial pressure of the conductive media as described in U.S. Pat. No. 8,288,288 (attorney docket no. NOVLP232), issued Oct. 12, 2012, which is incorporated herein by reference in its entirety and for all purposes. Other configurations for a localized cooling system for maintaining a relatively low substrate temperature can be utilized as is known in the art.

The temperature of the substrate can be maintained at a temperature below the agglomeration temperature of the metal using any of the cooling systems discussed earlier herein or as is known in the art. In some embodiments, the substrate can be maintained at a temperature between about −10° C. and about 150° C. In copper seed layers, for example, the substrate can be maintained at a temperature between about 75° C. and about 100° C. In cobalt seed layers, the substrate can be maintained at a temperature greater than about 100° C.

The duration of exposure to the plasma treatment can vary depending on the other process parameters. For example, the duration of exposure to the plasma treatment can be shortened by increasing remote plasma power, temperature of the reducing chamber, etc. In certain embodiments, the duration of the exposure to reduce the metal oxide surfaces to pure metal in an integrated film with the metal seed layer or semi-noble metal layer can be between about 1 second and about 60 minutes. For example, for pretreatment of copper seed layers, the duration of the exposure can between about 10 seconds and about 300 seconds.

While most reducing treatments may require that the substrate be rinsed and dried prior to plating in order to clean the substrate surface, the substrate as exposed to a plasma treatment need not be rinsed and dried prior to plating. Thus, reducing metal oxide surfaces using a plasma treatment can avoid the additional step of rinsing and drying the substrate before plating, which can further reduce the effects of reoxidation.

In some implementations, the metal in the metal seed layer or semi-noble metal layer may be reflowed as a result of exposure to one or more of increased temperature, reduced pressure, UV radiation from a UV source, UV radiation from the remote plasma, and radicals, ions, and other charged species from the remote plasma. Such exposure can lead to atoms in the metal seed layer or semi-noble metal layer to enter a more excited state and become more mobile. The atoms can move around on an underlying layer to reduce voids/gaps. As a result, a more uniform and continuous metal seed layer or semi-noble metal layer can be created. In some implementations, the reflow and the reduction treatment can occur simultaneously.

At step 225b in FIG. 2B, the substrate may be transferred under ambient conditions or under a blanket of inert gas to an electroplating system, electroless plating system, metal deposition system, or pretreating apparatus. Though metal oxides in the metal seed layer or semi-noble metal layer have been substantially reduced by exposing the metal oxide surfaces to a reducing gas atmosphere, performing step 225b may present an additional challenge of reoxidation from exposure to the ambient environment. In some embodiments, exposure to ambient conditions may be minimized using techniques such as shortening the duration of transfer or controlling the atmosphere during transfer. Additionally or alternatively, the transfer is conducted in a controlled environment that is less oxidizing than ambient conditions. To control the atmosphere during transfer, for example, the atmosphere may be substantially devoid of oxygen. The environment may be substantially inert and/or be low pressure or vacuum. In some embodiments, the substrate may be transferred under a blanket of inert gas. As discussed below, the transfer in step 225b may occur from a remote plasma apparatus to an electroplating system, where the remote plasma apparatus is integrated or otherwise connected to the electroplating system. At step 230b, metal may be plated on to the substrate.

The present disclosure provides methods for treating a substrate using atmospheric plasma. Treating the substrate can include removing contaminants from the surface of the substrate. For example, treating the substrate can include removing hydrogen and/or carbon atoms from a low-k dielectric layer, removing oxide from a metal seed layer or semi-noble metal layer prior to plating metal, cleaning a copper or tungsten surface prior to deposition of a hard mask layer, etc. Instead of exposing the substrate to plasma in a reduced pressure environment or vacuum environment, the substrate is exposed to plasma under atmospheric pressure. In some implementations, the atmospheric pressure can be greater than about 10 Torr, greater than about 50 Torr, or between about 50 Torr and about 760 Torr.

### Method of Treating a Substrate Using Atmospheric Plasma

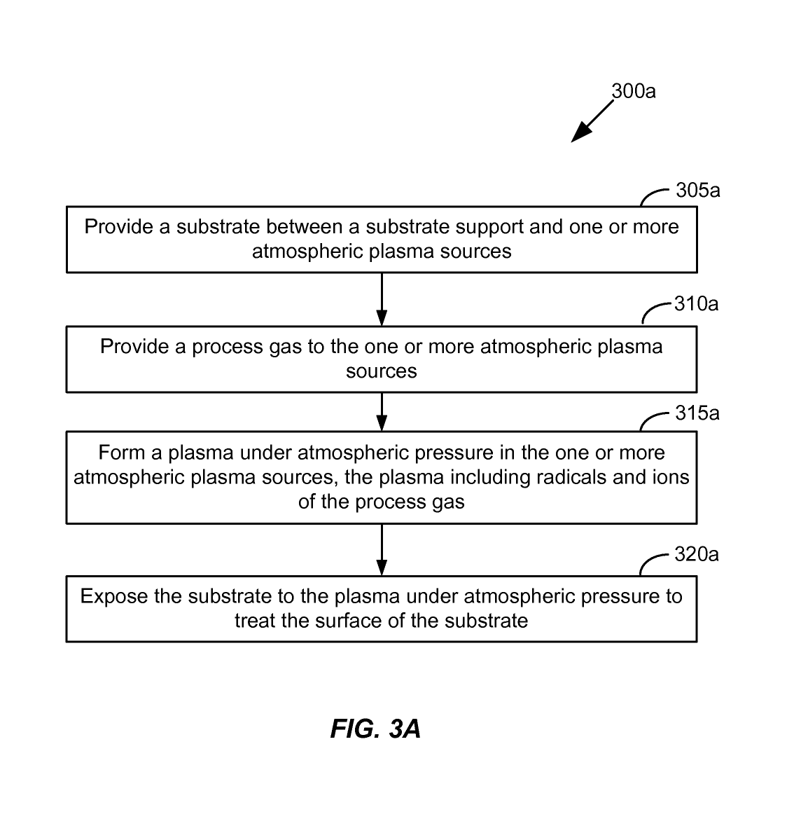

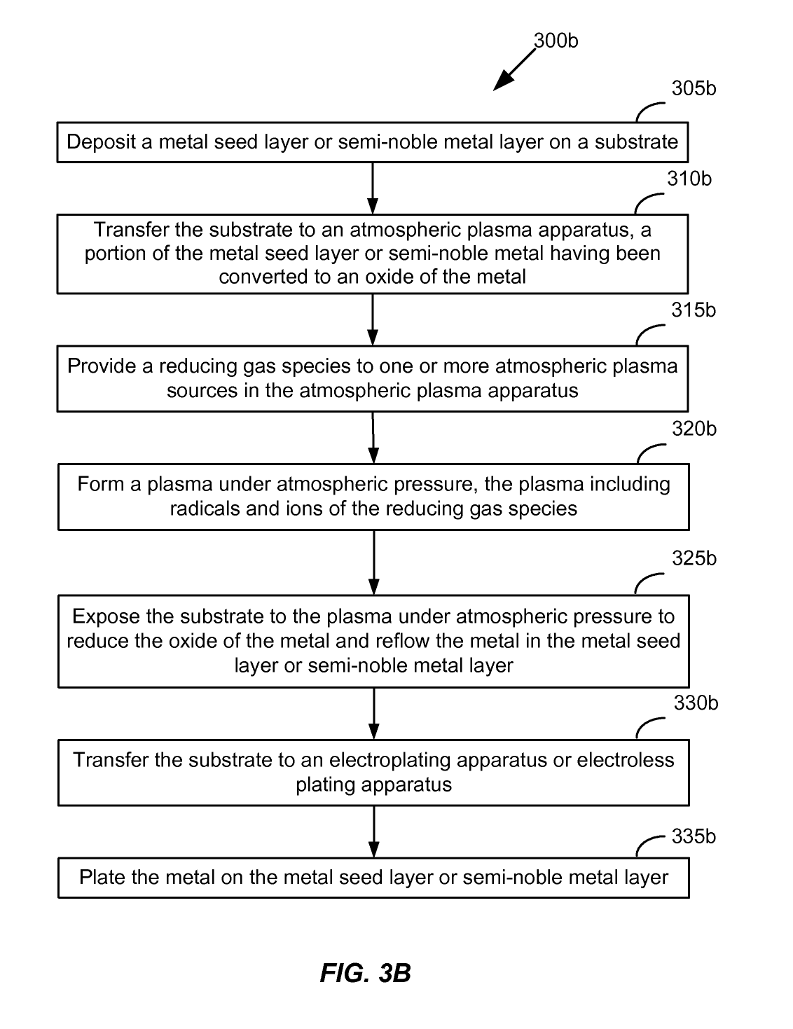

A method of treating a substrate using atmospheric plasma can be disclosed. FIG. 3A shows an exemplary flow diagram illustrating a method of treating a substrate using atmospheric plasma. The operations in a process 300a may be performed in different orders and/or with different, fewer, or additional operations.

The process 300a can begin with step 305a where a substrate is provided between a substrate support and one or more atmospheric plasma sources. A first layer may be formed on the surface of the substrate. The first layer can include, for example, a metal layer such as a PVD-deposited metal seed layer or semi-noble metal layer. The first layer can include a polished metal or dielectric layer, such as a post-CMP copper or tungsten layer. The first layer can include a low-k dielectric layer. The first layer may include one or more contaminants. For example, the PVD-deposited metal seed layer or semi-noble metal layer can include metal oxides and/or carbon compounds. The surface of the post-CMP copper or tungsten layer can include any number of surface residues and contaminants. The low-k dielectric material can include hydrogen and/or carbon atoms. In some implementations, the substrate may include features, such as recesses, vias, or trenches, which may be similarly described with reference to step 205a in FIG. 2A. The features may include recesses, vias, or trenches having a height to width aspect ratio of greater than about 3:1, greater than about 5:1, or greater than about 10:1.

The one or more atmospheric plasma sources can include one or more plasma generators that operate in an atmospheric or high pressure environment. An atmospheric or high pressure environment can include a pressure of greater than about 10 Torr, greater than about 50 Torr, or between about 50 Torr and about 760 Torr. The one or more atmospheric plasma sources can generate plasma by DC excitation, which can include an electric arc, and AC excitation, which can include a corona discharge, a dielectric barrier discharge, and plasma jets. For example, the one or more plasma sources can include a plurality of plasma jets. To generate plasma using the one or more atmospheric plasma sources, a high voltage discharge can be applied, the high voltage discharge being between about 100 V and about 50,000 V, or between about 5,000 V and about 15,000 V, the high voltage discharge having a frequency between about 1 kHz and about 20 MHz.

The substrate may be provided on a substrate support such as a pedestal. In some implementations, the substrate support may use a cooling or heating system to control the temperature of the substrate. For example, the substrate support can include an actively cooled pedestal to cool the substrate, and the substrate support may include heating elements to heat the substrate. In some implementations, the movable members may create a gap between the substrate and the substrate support to control the temperature of the substrate.

The substrate support may include one or more movable members or lift pins to position the substrate at a distance from the one or more atmospheric plasma sources. In some implementations, the distance between the substrate and the atmospheric plasma sources may be on the order of millimeters, such as between about 0.1 mm and about 10 mm, or between about 0.1 mm and about 3 mm. In some implementations, a showerhead may be disposed between the substrate and the one or more atmospheric plasma sources. The distance between the substrate and a showerhead can be between about 0.1 mm and about 10 mm, or between about 0.1 mm and about 3 mm. Thus, the substrate may be provided between the substrate support and the one or more atmospheric plasma sources so that the substrate may be positioned relatively close to the one or more atmospheric plasma sources. The position of a substrate support with respect to one or more atmospheric plasma sources may be on the order of millimeters, whereas the position of a substrate support with respect to other plasma sources can be on the order of centimeters and tens of centimeters.

Typically, low pressure plasmas can be generated at a distance on the order of centimeters from the substrate, because the radicals and ions in low pressure plasmas can generally be considered as substantially non-interacting. However, high pressure plasmas can be generated at a distance on the order of millimeters from the substrate, because the radicals and ions in the high pressure plasmas can be considered as constantly interacting. In high pressure plasmas, the reactive species can undergo rapid recombination within a very short distance. Hence, the mean free path of ions and radicals in high pressure plasmas before reaching a surface of a substrate can be relatively small. This can make control of radicals and ions reacting at the surface of the substrate difficult in high pressure plasmas.

The process 300a can continue at step 310a, where a process gas is provided to the one or more atmospheric plasma sources. It will be understood that any suitable process gas or combination of gases may be used to form the plasma. The process gas can include a gas mixture of a reactive gas species and an inert (diluting) gas species. Examples of reactive gas species can include but are not limited to hydrogen, ammonia, and hydrazine. Examples of inert gas species can include but are not limited to nitrogen, helium, argon, neon, krypton, xenon, and radon.

The process gas may be provided by flowing the process gas into a discharge section of the one or more atmospheric plasma sources. In a plasma jet, the process gas is flowed to a discharge section and excited and converted to plasma. The plasma passes through a jet head to the surface of the substrate to be treated. In a dielectric barrier discharge, a process gas can be delivered to a space between two electrodes. In some implementations, the surface of the substrate can act as a dielectric barrier. In some implementations, a dielectric-coated or ceramic-bonded metal showerhead can serve as a dielectric barrier. In a hollow cathode, the process gas is flowed through a hollow cathode and enters a space between the hollow cathode and an electrode.

The process 300a can continue at step 315a, where plasma is formed under atmospheric pressure in the one or more atmospheric plasma sources. The plasma can include radicals and ions of the process gas. In some implementations, the plasma includes radicals and ions of the process gas as well as photons (e.g., UV radiation) generated from the process gas. To form the plasma, a pulse generator can apply a high voltage discharge to the one or more atmospheric plasma sources. The pulse generator can apply a voltage greater than a breakdown voltage of the process gas. In some implementations, the applied voltage can be between about 100 V and about 50,000 V, such as between about 5,000 V and about 15,000 V.

The plasma may be formed at a high pressure or at atmospheric pressure, where the pressure can be greater than about 10 Torr, greater than about 50 Torr, or between about 50 Torr and about 760 Torr. By operating at high pressures, the atmospheric plasma can avoid costly vacuum equipment, load locks, and robotic assemblies. The plasma may be formed without vacuum pumping the chamber or bringing the chamber to a reduced pressure, the reduced pressure being between about 0.1 Torr and about 5 Torr.

In some implementations, the plasma may be formed and delivered to a substrate without containment in a processing chamber or a reaction vessel. This can reduce any additional costs associated with providing a separate containment structure for treating the substrate prior to deposition. The process gas in such implementations can be a gas mixture having a reduced concentration of reactive species and an increased concentration of diluting species. The increased concentration of diluting species can be introduced for safety reasons. For example, the process gas may include a forming gas. The forming gas can include a mixture of hydrogen and nitrogen. The concentration of hydrogen can be less than about 50% or less than about 10% of the forming gas. The concentration of nitrogen can be greater than about 50% or greater than about 90% of the forming gas.

While in some implementations the plasma may be formed in ambient conditions without containment in a processing chamber or reaction vessel, other implementations may form and deliver the plasma to the substrate inside a processing chamber. The processing chamber may provide pumps, ventilation, and safety features in containing the process gas and plasma. In such implementations, the process gas can be a pure gas of reactive species or a gas mixture having an increased concentration of reactive species and a reduced concentration of diluting species. For example, the process can substantially include at least one of hydrogen and ammonia, where the at least one of the hydrogen and the ammonia is greater than 90% of a gas mixture. Furthermore, the pressure of the environment in which the plasma is formed can be adjusted. For example, the pressure in the processing chamber can be adjusted by flowing inert gas or any other suitable gas into the processing chamber. Flowing an inert gas not only pressurizes the processing chamber, but can also reduce the amount of oxygen in the processing chamber.

In some implementations, the plasma may be formed at a temperature between about 0° C. and about 400° C. This can depend in part on the material of the first layer being treated. For example, if the first layer includes copper, the plasma may be formed at a temperature between about 0° C. and about 75° C. If the first layer includes cobalt, the plasma may be formed at a temperature between about 100° C. and about 400° C. In some implementations, the plasma also may be formed at a low temperature or atmospheric temperature, where the temperature can be less than about 150° C., less than about 75° C., less than about 50° C., or between about 5° C. and about 30° C. Typical plasmas may be generated under conditions that are relatively hot. However, such plasmas may heat up the substrate and can lead to unintended effects, including agglomeration of a seed layer. When the plasma is formed at a low temperature or atmospheric temperature, the substrate can be more easily maintained at desired temperature levels. In some implementations, the plasma may be formed and delivered to the substrate without using any cooling system to actively cool the substrate.

The process 300a can continue at step 320a, where the substrate is exposed to the plasma under atmospheric pressure to treat the surface of the substrate. The radicals, ions, and/or photons (e.g., UV radiation) from the process gas may react with the first layer of the substrate. Treatment of the first layer on the substrate may remove contaminants in the first layer prior to deposition of a second layer.

The first layer may be treated by exposure to the plasma under atmospheric pressure. For example, the first layer may include a metal seed layer or semi-noble metal layer, where the treatment of the first layer can include removal of oxides, carbon compounds, or other contaminants from the metal seed layer or semi-noble metal layer. The first layer may include a post-CMP copper or tungsten layer, where treatment of the first layer may remove surface residues and other contaminants from the post-CMP copper or tungsten layer. The first layer may include a low-k dielectric material, where treatment of the first layer may remove hydrogen and/or carbon atoms from the low-k dielectric material.

Control over the distribution and uniformity of the plasma across a substrate surface may be difficult with atmospheric plasmas. However, for treatment of a substrate surface, as opposed to deposition of material on a substrate surface, precise control across the substrate surface may not be as critical. What may be more critical is the amount of radicals produced at the substrate surface. Atmospheric plasma sources can produce a relatively high density of radicals at a surface of the substrate by controlling the gas mixture, the distance between the substrate and the plasma sources, the pressure, and the applied voltage. Atmospheric plasma sources may provide greater control over the generation of radicals by controlling one or more of the aforementioned parameters. For example, the distance between the substrate surface and the one or more plasma sources can be less than about 10 mm, or between about 0.1 mm and about 3 mm.

In some implementations, the relatively high density of radicals formed at the surface of the substrate can be useful in treating a substrate with a plurality of vias or trenches. Increasing the density of radicals can increase the likelihood of radicals reaching the bottom of recesses, vias, or trenches, especially for high aspect ratio recesses, vias, or trenches. Hence, the plasma formed by the one or more atmospheric plasma sources may more effectively treat a crenulated surface.

In some implementations, the process 300a can further include transferring the substrate under atmospheric conditions to a deposition apparatus. Because the substrate is already exposed to atmospheric conditions during treatment, the substrate may be transferred without additional robot assemblies, load locks, cooling systems, and chambers. This can increase throughput and reduce the costs associated with maintenance and operation of additional equipment.

In some implementations, the process 300a can further include depositing a second layer over the first layer after exposing the first layer to the plasma. For example, where the first layer includes a metal seed layer or semi-noble metal layer, the second layer can include a bulk electroplated metal layer. Where the first layer includes a post-CMP copper or tungsten layer, the second layer can include a hard mask layer. Where the first layer includes a low-k dielectric, the second layer can include an etch stop layer.

A method of reducing metal oxides on a substrate surface using atmospheric plasma can be disclosed. FIG. 3B shows an exemplary flow diagram illustrating a method of treating a substrate using atmospheric plasma to reduce metal oxides prior to plating metal on the substrate. The operations in a process 300b may be performed in different orders and/or with different, fewer, or additional operations.

The process 300b can begin at step 305b where a metal seed layer or semi-noble metal layer is deposited on a substrate. A metal seed layer such as a copper seed layer may be deposited on the substrate using a suitable deposition technique such as PVD. The metal seed layer or semi-noble metal layer may have an average thickness of about 15 Å to about 100 Å or larger. In some embodiments, the metal seed layer or semi-noble metal layer can have a thickness between about 40 Å and about 80 Å. The substrate may have recesses, vias, or trenches having height to width aspect ratios of greater than about 3:1, greater than about 5:1, or greater than about 10:1.

The process 300b can continue at step 310b where the substrate is transferred to an atmospheric plasma apparatus, a portion of the metal seed layer or semi-noble metal layer having been converted to an oxide of the metal. The atmospheric plasma apparatus can be part of a processing chamber. In some implementations, the transfer in step 310b can occur in a transfer chamber prior to providing the substrate to the processing chamber. The transfer chamber may be filled or pressurized with inert gas, such as nitrogen gas. As a result, the environment may be substantially devoid of oxygen to reduce the effects of reoxidation. Prior to transfer or during transfer, the metal seed layer or the semi-noble metal layer may be exposed to ambient conditions to convert metal to metal oxide. The as-provided metal seed layer or semi-noble metal layer with portions converted to oxide of the metal may lead to further problems of void formation, pitting, non-uniform plating within the features, and adhesion/delamination issues caused by poor interface quality. In some embodiments, a substantial portion of the metal seed layer or semi-noble metal layer can be converted to oxide, such as more than about 50%, more than about 70%, more than about 90%, or more than about 95% of elemental composition of the metal layer being converted to metal oxide.

The process 300b can continue at step 315b where a reducing gas species is provided to one or more atmospheric plasma sources in the atmospheric plasma apparatus. The atmospheric plasma apparatus may be part of or include a processing chamber, where the processing chamber may be filled or pressurized with inert gas. The reducing gas species can include H₂, NH₃, CO, B₂H₆, sulfite compounds, carbon and/or hydrocarbons, phosphites, and/or N₂H₄. The reducing gas species can be part of a gas mixture, where the gas mixture includes the reducing gas species and an inert (diluting) gas species. Examples of inert gas species can include but are not limited to nitrogen, helium, argon, neon, krypton, xenon, and radon. The reducing gas species may be provided in a discharge section of the one or more atmospheric plasma sources. For example, where the one or more atmospheric plasma sources include a dielectric barrier discharge, the reducing gas species may flow into a space between a metal electrode and a dielectric barrier in the processing chamber. In some implementations, the surface of the substrate can act as a dielectric barrier. In some implementations, a dielectric-coated or ceramic-bonded metal showerhead can serve as a dielectric barrier.

The process 300b can continue at step 320b where plasma is formed under atmospheric pressure. The plasma includes radicals and ions of the reducing gas species. In some implementations, the plasma includes radicals, ions, and photons (e.g., UV radiation) from the reducing gas species. To form the plasma, a pulse generator can apply a high voltage discharge to the one or more atmospheric plasma sources. The pulse generator can apply a voltage greater than a breakdown voltage of the gas. In some implementations, the applied voltage can be between about 100V and about 50,000 V, such as between about 5,000 V and about 15,000 V. The plasma may be formed at a high pressure or at atmospheric pressure, where the pressure can be greater than about 10 Torr, greater than about 50 Torr, or between about 50 Torr and about 760 Torr. The plasma also may be formed at a low temperature or atmospheric temperature, where the temperature can be less than about 150° C., less than about 50° C., or between about 5° C. and about 30° C.

The process 300b can continue at step 325b where the substrate is exposed to the plasma under atmospheric pressure to reduce the oxide of the metal and reflow the metal in the metal seed layer or semi-noble metal layer. In step 325b, the interaction of the plasma with the metal seed layer or the semi-noble metal layer and the processing conditions may be similar to the interaction of the plasma and the processing conditions discussed earlier herein with respect to step 220b of FIG. 2B. In some embodiments, the plasma may reduce the oxide of the metal to a metal in the form of a film integrated with the metal seed layer or semi-noble metal layer. The radicals of the reducing gas species, ions of the reducing gas species, ultraviolet (UV) radiation from the reducing gas species, or the reducing gas species itself react with the metal oxide under conditions that can convert the metal oxide to metal in the form of a film integrated with the metal seed layer or semi-noble metal layer. Characteristics of the film integrated with the metal seed layer or semi-noble metal layer are discussed in further detail with respect to FIG. 4D.

FIGS. 4A-4D show examples of cross-sectional schematics of a metal layer deposited on a conductive barrier layer. However, it will be understood by a person of ordinary skill in the art that the metal layer may be part of the conductive barrier layer.

FIG. 4A shows an example of a cross-sectional schematic of an oxidized metal layer deposited over a conductive barrier layer 419. The metal layer may include a semi-noble metal layer upon which a copper seed layer may be formed subsequently thereon. As discussed earlier herein, the metal layer 420 may be oxidized upon exposure to oxygen or water vapor in ambient conditions, which can convert metal to a metal oxide 425 in a portion of the metal layer 420.

FIG. 4B shows an example of a cross-sectional schematic of a metal layer with a void due to removal of metal oxide. As discussed earlier herein, some solutions treat the metal oxide 425 by removal of the metal oxide 425, resulting in voids 426. For example, the metal oxide 425 can be removed by oxide etching or oxide dissolution by an acid or other chemical. Because the thickness of the void 426 can be substantially large relative to the thinness of the metal layer 420, the effect of the void 426 on subsequent plating can be significant.

FIG. 4C shows an example of a cross-sectional schematic of a metal layer with reduced metal oxide forming a reaction product not integrated with the metal layer. As discussed earlier herein, some treatments reduce the metal oxide 425 under conditions that agglomerate metal with the metal layer 420. In some embodiments, reducing techniques generate metal particles 427, such as copper powder, that can agglomerate with the metal layer 420. The metal particles 427 do not form an integrated film with the metal layer 420. Instead, the metal particles 427 are not continuous, conformal, and/or adherent to the metal layer 420.

FIG. 4D shows an example of a cross-sectional schematic of a metal layer with reduced metal oxide forming a film integrated with the metal layer. In some embodiments, radicals from a reducing gas species, ions from the reducing gas species, UV radiation from the reducing gas species, or the reducing gas species itself can reduce the metal oxide 425. When process conditions for the reducing gas atmosphere are appropriately adjusted, the metal oxide 425 in FIG. 4A may convert to a film 427 integrated with the metal layer 420. The film 427 is not a powder. In contrast to the example in FIG. 4C, the film 427 can have several properties that integrate it with the metal layer 420. For example, the film 427 can be substantially continuous and conformal over the contours metal layer 420. Moreover, the film 427 can be substantially adherent to the metal layer 420, such that the film 427 does not easily delaminate from the metal layer 420.

Returning to FIG. 3B, the process 300b can continue at step 330b where the substrate is transferred to an electroplating or electroless plating apparatus. In some implementations, the transfer in step 330b can occur in a transfer chamber, where the transfer may occur under a blanket of inert gas. That way, exposure to ambient conditions may be minimized or otherwise reduced. For example, the transfer chamber may be pressurized or otherwise filled with nitrogen gas. In some implementations, the transfer chamber may include a cooling system, such as an actively cooled pedestal, to control the temperature of the substrate after exposure of the substrate to the plasma. In addition or in the alternative, the substrate may be exposed to a cooling gas, where the cooling gas can include at least one of argon, helium, and nitrogen. In some implementations, the temperature of the substrate can be maintained between about −10° C. and about 150° C.

The process 300b can continue at step 335b where the metal is plated on the metal seed layer or semi-noble metal layer. In some implementations, plating the metal can include bulk deposition of metal using a plating bath in the electroplating apparatus. The plating bath used for bulk deposition of metal can fill features, including high aspect ratio recesses, vias, and trenches. Examples of electroplating methods for depositing bulk copper fill can be described in U.S. Pat. No. 6,946,065 (attorney docket no. NOVLP071D1) and also in U.S. Pat. No. 7,799,674 (attorney docket no. NOVLP207), both of which are incorporated herein by reference in their entirety and for all purposes. Depositing the bulk layer of copper may be achieved by electroplating, which can be difficult if the seed layer is very thin and discontinuous. However, reducing metal oxides using atmospheric plasma on the semi-noble metal layer and/or the metal seed layer can reduce the discontinuities and voids in the seed layer for more uniform plating. The atmospheric plasma treatment may also increase the conductivity of the metal seed layer or semi-noble metal layer by removing organic impurities left behind from the as-deposited metal seed layer or semi-noble metal layer.

Electroplating Apparatus with Atmospheric Plasma Apparatus

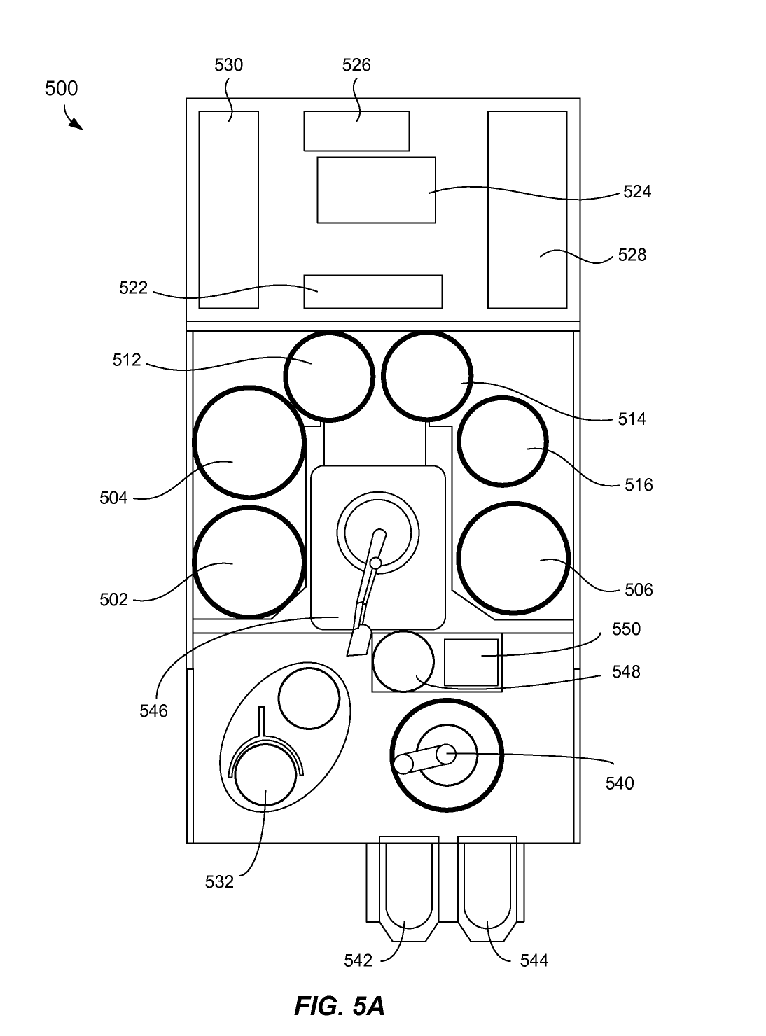

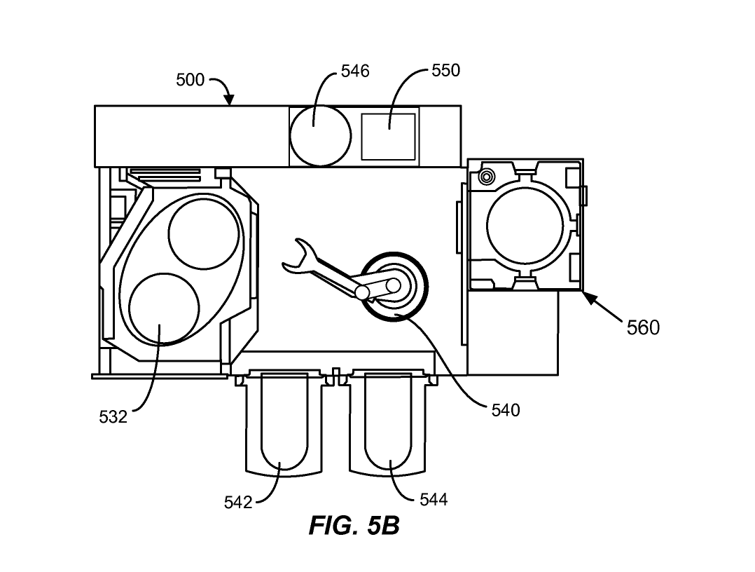

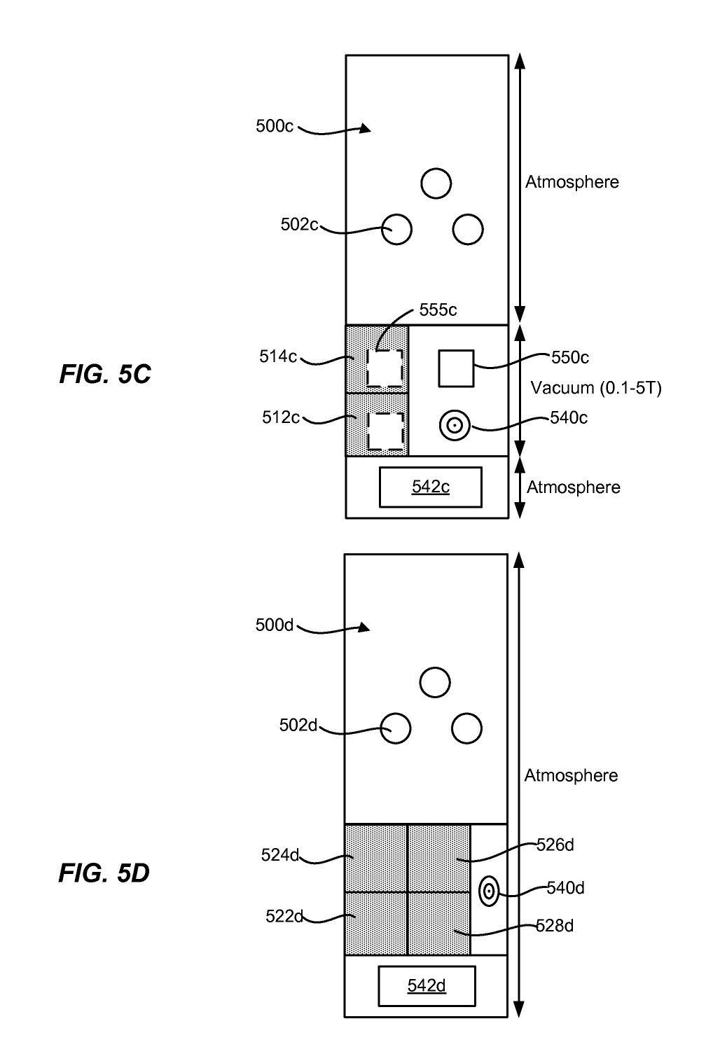

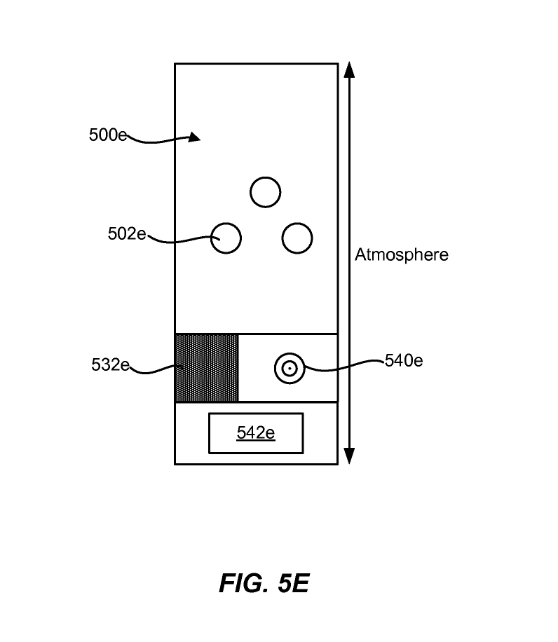

FIG. 5A shows an example of a top view schematic of an electroplating apparatus. The electroplating apparatus 500 can include three separate electroplating modules 502, 504, and 506. The electroplating apparatus 500 can also include three separate modules 512, 514, and 516 configured for various process operations. For example, in some embodiments, modules 512 and 516 may be spin rinse drying (SRD) modules and module 514 may be an annealing station. However, the use of SRD modules may be rendered unnecessary after exposure to a plasma treatment. In some embodiments, at least one of the modules 512, 514, and 516 may be post-electrofill modules (PEMs), each configured to perform a function, such as edge bevel removal, backside etching, acid cleaning, spinning, and drying of substrates after they have been processed by one of the electroplating modules 502, 504, and 506.

The electroplating apparatus 500 can include a central electroplating chamber 524. The central electroplating chamber 524 is a chamber that holds the chemical solution used as the plating solution in the electroplating modules 502, 504, and 506. The electroplating apparatus 500 also includes a dosing system 526 that may store and deliver additives for the plating solution. A chemical dilution module 522 may store and mix chemicals that may be used as an etchant. A filtration and pumping unit 527 may filter the plating solution for the central electroplating chamber 524 and pump it to the electroplating modules 502, 504, and 506.

In some embodiments, an annealing station 532 may be used to anneal substrates as pretreatment. The annealing station 532 may include a number of stacked annealing devices, e.g., five stacked annealing devices. The annealing devices may be arranged in the annealing station 532 one on top of another, in separate stacks, or in other multiple device configurations.

A system controller 530 provides electronic and interface controls required to operate the electroplating apparatus 500. The system controller 530 (which may include one or more physical or logical controllers) controls some or all of the properties of the electroplating apparatus 500. The system controller 530 typically includes one or more memory devices and one or more processors. The processor may include a central processing unit (CPU) or computer, analog and/or digital input/output connections, stepper motor controller boards, and other like components. Instructions for implementing appropriate control operations as described herein may be executed on the processor. These instructions may be stored on the memory devices associated with the system controller 530 or they may be provided over a network. In certain embodiments, the system controller 530 executes system control software.

The system control software in the electroplating apparatus 500 may include electroplating instructions for controlling the timing, mixture of the electrolyte components, inlet pressure, plating cell pressure, plating cell temperature, substrate temperature, current and potential applied to the substrate and any other electrodes, substrate position, substrate rotation, and other parameters performed by the electroplating apparatus 500. System control software may be configured in any suitable way. For example, various process tool component sub-routines or control objects may be written to control operation of the process tool components necessary to carry out various process tool processes. System control software may be coded in any suitable computer readable programming language.

In some embodiments, system control software includes input/output control (IOC) sequencing instructions for controlling the various parameters described above. For example, each phase of an electroplating process may include one or more instructions for execution by the system controller 530, and each phase of the pretreatment or reducing process may include one or more instructions for execution by the system controller 530. In electroplating, the instructions for setting process conditions for an immersion process phase may be included in a corresponding immersion recipe phase. In pretreatment or reducing treatment, the instructions for setting process conditions for exposing the substrate to a plasma may be included in a corresponding reducing phase recipe. In some embodiments, the phases of electroplating and reducing processes may be sequentially arranged, so that all instructions for a process phase are executed concurrently with that process phase.

Other computer software and/or programs may be employed in some embodiments. Examples of programs or sections of programs for this purpose include a substrate positioning program, an electrolyte composition control program, a pressure control program, a heater control program, a potential/current power supply control program. Other examples of programs or sections of this program for this purpose include a timing control program, movable members positioning program, a substrate support positioning program, a plasma apparatus control program, a pressure control program, a substrate support temperature control program, a showerhead temperature control program, a cooling gas control program, and a gas atmosphere control program.

In some embodiments, there may be a user interface associated with the system controller 530. The user interface may include a display screen, graphical software displays of the apparatus and/or process conditions, and user input devices such as pointing devices, keyboards, touch screens, microphones, etc.

Signals for monitoring the process may be provided by analog and/or digital input connections of the system controller 530 from various process tool sensors. The signals for controlling the process may be output on the analog and digital output connections of the process tool. Non-limiting examples of process tool sensors that may be monitored include mass flow controllers, pressure sensors (such as manometers), thermocouples, etc. Appropriately programmed feedback and control algorithms may be used with data from these sensors to maintain process conditions, such as temperature of the substrate.

A hand-off tool 540 may select a substrate from a substrate cassette such as the cassette 542 or the cassette 544. The cassettes 542 or 544 may be front opening unified pods (FOUPs). A FOUP is an enclosure designed to hold substrates securely and safely in a controlled environment and to allow the substrates to be removed for processing or measurement by tools equipped with appropriate load ports and robotic handling systems. The hand-off tool 540 may hold the substrate using a vacuum attachment or some other attaching mechanism.

The hand-off tool 540 may interface with the annealing station 532, the cassettes 542 or 544, a transfer station 550, or an aligner 548. From the transfer station 550, a hand-off tool 546 may gain access to the substrate. The transfer station 550 may be a slot or a position from and to which hand-off tools 540 and 546 may pass substrates without going through the aligner 548. In some embodiments, however, to ensure that a substrate is properly aligned on the hand-off tool 546 for precision delivery to an electroplating module, the hand-off tool 546 may align the substrate with an aligner 548. The aligner 548 can include alignment pins against which the hand-off tool 540 pushes the substrate. When the substrate is properly aligned against the alignment pins, the hand-off tool 540 moves to a preset position with respect to the alignment pins. The hand-off tool 546 may also deliver a substrate to one of the electroplating modules 502, 504, or 506 or to one of the three separate modules 512, 514, and 516 configured for various process operations.

The metal seed layer may be electroplated onto the substrate in one of the electroplating modules 502, 504, and 506. After the seed layer electroplating operation completes, the hand-off tool 540 may remove the substrate from one of the electroplating modules 502, 504, and 706, and may transport the substrate to one of the PEMs 512, 514, and 516. For example, one of the PEMs 512, 514, and 516 may clean, rinse, dry, or otherwise treat the substrate. The substrate can then be picked up with the hand-off tool 540 and placed in the transfer station 550. The transfer station 550 may be a slot or a position from and to which hand-off tool 540 and 546 may pass substrates without going through the aligner 548. The hand-off tool 540 then moves the substrate from the transfer chamber 550, optionally to the cassette, or to one of the anneal stations or remote plasma apparatus. If the substrate is inserted into the cassette, it may be stored for treatment and bulk electroplating at a later time. Alternatively, it may be simply moved to the anneal station or plasma apparatus. Afterwards, the hand-off tool 540 can move the substrate back through the aligner 548 and the hand-off tool 546 to one of the electroplating modules 502, 504, and 506 for bulk electroplating. After the features are filled with metal, the substrate can be moved to one of the PEMs 512, 514, and 516. In some instances, unwanted metal from certain locations on the substrate (namely the edge bevel region and the backside) can be etched away by an etchant solution provided by chemical dilution module 522. The PEMs 512, 514, and 516 can also clean, rinse, dry, or otherwise treat the substrate.

In some embodiments, a remote plasma apparatus may be part of or integrated with the electroplating apparatus 500. FIG. 5B shows an example of a magnified top view schematic of a remote plasma apparatus with an electroplating apparatus. However, it is understood by those of ordinary skill in the art that the remote plasma apparatus may alternatively be attached to an electroless plating apparatus or other metal deposition apparatus. The remote plasma apparatus 560 may be attached to the side of the electroplating apparatus 500. The remote plasma apparatus 560 may be connected to the electroplating apparatus 500 in such a way so as to facilitate efficient transfer of the substrate to and from the remote plasma apparatus 560 and the electroplating apparatus 500. The hand-off 540 may gain access to the substrate from cassette 542 or 544. The hand-off tool 540 may pass the substrate to the remote plasma apparatus 560 for exposing the substrate to a remote plasma treatment and a cooling operation. The hand-off tool 540 may pass the substrate from the remote plasma apparatus 560 to the transfer station 550. In some embodiments, the aligner 548 may align the substrate prior to transfer to one of the electroplating modules 502, 504, and 506 or one of the three separate modules 512, 514, and 516.

In some embodiments, the system controller 530 may control the parameters for the process conditions in the remote plasma apparatus 560. Non-limiting examples of such parameters include substrate support temperature, showerhead temperature, substrate support position, movable members position, cooling gas flow, cooling gas temperature, process gas flow, process gas pressure, venting gas flow, venting gas, reducing gas, plasma power, and exposure time, transfer time, etc. These parameters may be provided in the form of a recipe, which may be entered utilizing the user interface as described earlier herein.

Operations in the remote plasma apparatus 560 that is part of the electroplating apparatus 500 may be controlled by a computer system. The program instructions may include instructions to perform all of the operations needed to reduce metal oxides to metal in a semi-noble metal layer or metal seed layer. The program instructions may also include instructions to perform all of the operations needed to cool the substrate, position the substrate, and load/unload the substrate.

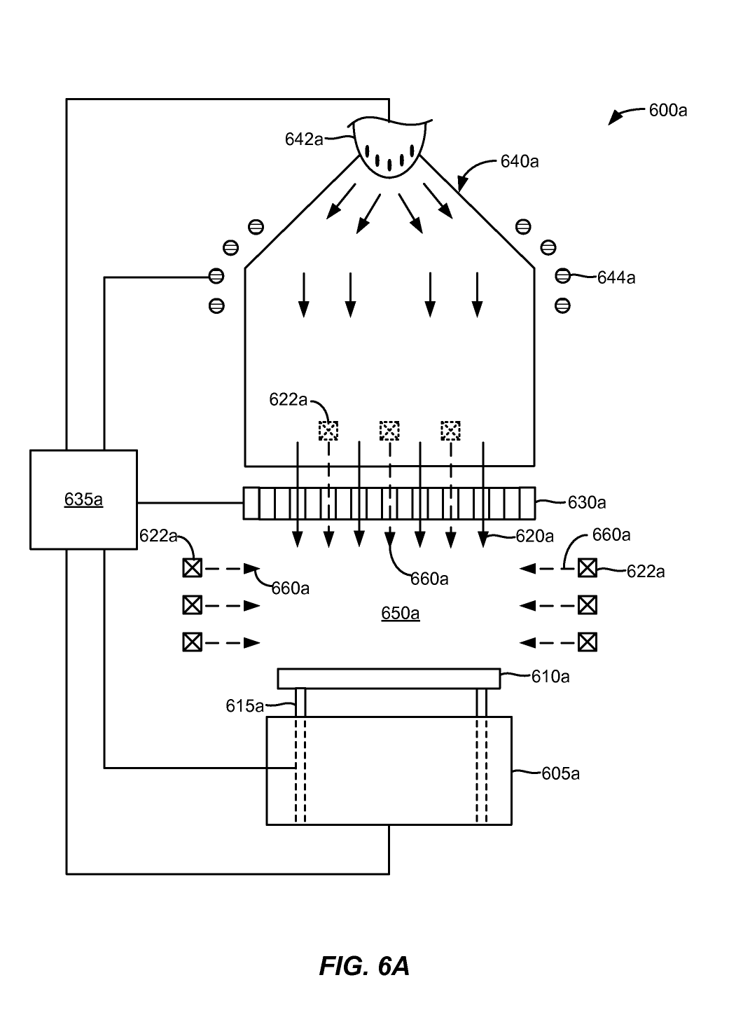

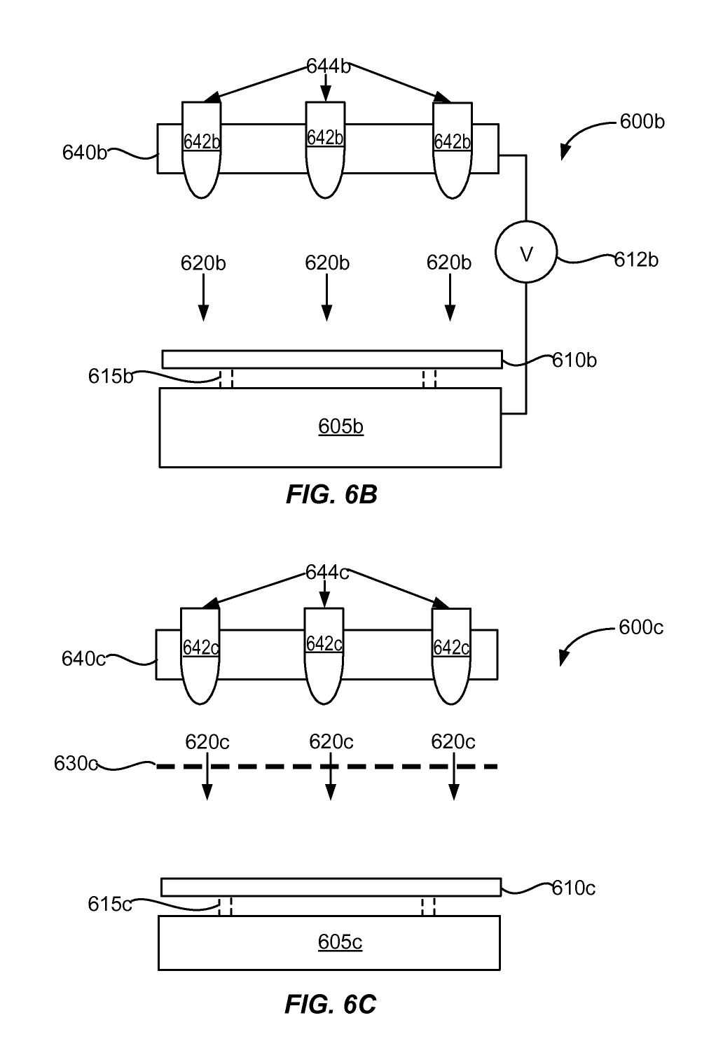

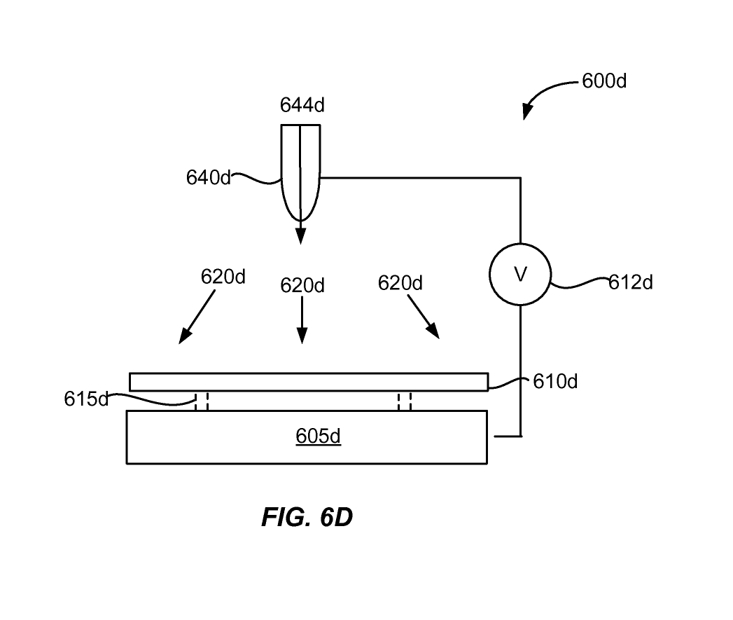

FIG. 5C shows an example of a block diagram of an electroplating apparatus for a low pressure system. The diagram illustrates an electroplating apparatus 500c including a plurality of regions. An operating pressure range is indicated for each region of the electroplating apparatus 500c. A substrate can undergo a series of processing steps through each region prior to electroplating metal on the substrate, where the substrate can be exposed to different environmental conditions in each processing step. In FIG. 5C, a FOUP 542 may receive a substrate so that the substrate can be loaded in the electroplating apparatus 500c. The FOUP 542 may receive the substrate in atmospheric conditions, where the pressure may be greater than about 10 Torr, greater than about 50 Torr, or between about 50 Torr and about 760 Torr. The robot assembly 540c may interface with the FOUP 542c to access and pick up the substrate from the FOUP 542c. The robot assembly 540c may pass the substrate to a slot or position in a transfer station 550c or transfer port. A load lock 555c may be coupled to the transfer station so that the load lock 555c can receive the substrate from the robot assembly 540c via the transfer station 550c. In some implementations, the robot assembly 540c and the transfer station 550c may hold the substrate in reduced or vacuum pressure. If not already, then the load lock 555c may be pumped down to reduced or vacuum pressure, where the pressure is between about 0.1 Torr and about 5 Torr. The load lock 555c may be equipped with or otherwise connected to a first plasma apparatus 512c or a second plasma apparatus 514c. Each of the first plasma apparatus 512c and the second plasma apparatus 514c can process the substrate with a direct or remote plasma under reduced or vacuum pressure. An example of a remote plasma apparatus can be described with reference to FIG. 6A. In some implementations, the substrate can be cooled by a showerhead, pedestal, cooling gas, or other cooling system prior to transferring the substrate to the electroplating module 502c. During transfer, the robot assembly 540c may receive the substrate from the load lock 555c via the transfer station 550c. The transfer station 550c may pass the substrate to the electroplating module 502c. When the substrate is transferred to the electroplating module 502c, the substrate can be exposed to atmospheric pressure, where the pressure can be greater than about 10 Torr, greater than about 50 Torr, or between about 50 Torr and about 760 Torr. After electroplating metal on the substrate, the substrate may be returned to the FOUP 542c.

An electroplating apparatus with an atmospheric plasma apparatus can be disclosed. Inclusion of an atmospheric plasma apparatus can reduce the amount of space otherwise occupied by a plasma apparatus operating in reduced or vacuum pressure. Equipment for vacuum pumping, load locks, and robot assemblies may be rendered unnecessary or otherwise eliminated because the electroplating apparatus can operate in the same environmental conditions in each processing step. This can reduce the cost of manufacture, operation, and maintenance of the electroplating apparatus. This also can increase the throughput for processing of substrates as well as decrease the footprint occupied by the electroplating apparatus.

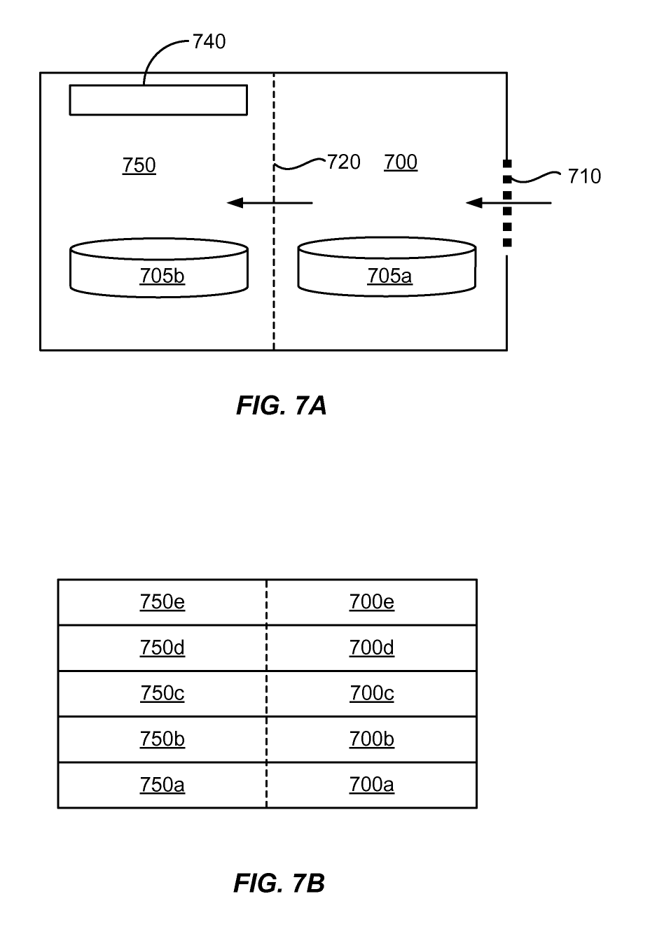

FIG. 5D shows an example of a block diagram of an electroplating apparatus for a high pressure system in some implementations. In an electroplating apparatus 500d, a substrate may be received, transferred, treated, and electroplated under high or atmospheric pressure, where the pressure can be greater than about 10 Torr, greater than about 50 Torr, or between about 50 Torr and about 760 Torr. A FOUP 542d can receive the substrate to load the substrate in the electroplating apparatus 500d, where the substrate is received under atmospheric conditions. A robot assembly 540d can operate under atmospheric conditions and transfer the substrate to a first plasma apparatus 522d, a second plasma apparatus 524d, a third plasma apparatus 526d, or a cooling station 528d. The first plasma apparatus 522d, second plasma apparatus 524d, or third plasma apparatus 526d may process the substrate with plasma under atmospheric pressure. In some implementations, the plasma apparatuses 522d, 524d, and 526d may each include a processing chamber to contain the plasma. In some embodiments, any of the plasma apparatuses 522d, 524d, and 526d may be an atmospheric plasma apparatus described with reference to FIGS. 6B-6D. In some implementations, the processing chamber may flow inert gas inside to minimize ambient oxygen, such as nitrogen gas. Without load locks, vacuum pumps, and other equipment to reduce pressure in the electroplating apparatus 500d, more space is available to include additional units such as plasma apparatuses, cooling stations, annealing chambers, etc. After treating the substrate via exposure to atmospheric plasma, the substrate can be transferred to an electroplating module 502d for electroplating under atmospheric pressure. In addition or in the alternative, the substrate may be cooled following exposure to atmospheric plasma in the cooling station 528d. In some implementations, the cooling station 528d may gain access to the substrate using a two-chamber configuration as illustrated in FIG. 7A.

FIG. 5E shows an example of a block diagram of an electroplating apparatus for a high pressure system in some implementations. An electroplating apparatus 500e may receive, transfer, treat, and electroplate a substrate under high or atmospheric pressure. In FIG. 5E, a FOUP 542e, a robot assembly 540e, stacked plasma apparatuses 532e, and an electroplating module 502e can operate in atmospheric conditions. Like the electroplating apparatus 500d in FIG. 5D, the electroplating apparatus 500e does not include load locks, vacuum pumps, and other equipment for reducing pressure. However, instead of a plurality of separate plasma apparatuses horizontally adjacent to one another, the electroplating apparatus 500e can include a vertical stack of a plurality of plasma apparatuses 532e in a single system or component. In some implementations, the stacked plasma apparatuses 532e can have a configuration identical or similar to the stacked configuration in FIG. 7B. Stacking the plasma apparatuses for treating the substrate by exposing to atmospheric plasma can increase throughput. In some implementations, each plasma apparatus can integrate a cooling stage with the plasma apparatus.

### Atmospheric Plasma Apparatus

A substrate can be treated using a remote plasma apparatus in a reduced pressure or vacuum environment. Aspects of a remote plasma apparatus can be described in U.S. Pat. No. 8,084,339 to Antonelli et al., filed Jun. 12, 2009, which is incorporated herein by reference in its entirety and for all purposes.

FIG. 6A shows an example of a cross-sectional schematic diagram of a remote plasma apparatus and a processing chamber. The remote plasma apparatus 600a includes a processing chamber 650a, which includes a substrate support 605a such as a pedestal for supporting a substrate 610a. The remote plasma apparatus 600a also includes a remote plasma source 640a over the substrate 610a, and a showerhead 630a between the substrate 610a and the remote plasma source 640a. A reducing gas species 620a can flow from the remote plasma source 640a towards the substrate 610a through the showerhead 630a. A remote plasma may be generated in the remote plasma source 640a to produce radicals of the reducing gas species 620a. The remote plasma source 640a may also produce ions and other charged species of the reducing gas species. The remote plasma may also generate photons, such as UV radiation, from the reducing gas species 620a. For example, coils 644a may surround the walls of the remote plasma source 640a and generate remote plasma in the remote plasma source 640a.

In some embodiments, the coils 644a may be in electrical communication with a radio frequency (RF) power source or microwave power source. An example of a remote plasma source 640a with an RF power source can be found in the GAMMA®, manufactured by Lam Research Corporation of Fremont, Calif. Another example of an RF remote plasma source 640a can be found in the Astron®, manufactured by MKS Instruments of Wilmington, Mass., which can be operated at 440 kHz and can be provided as a subunit bolted onto a larger apparatus for processing one or more substrates in parallel. In some embodiments, a microwave plasma can be used with the remote plasma source 640a, as found in the Astex®, also manufactured by MKS Instruments. A microwave plasma can be configured to operate at a frequency of 2.45 GHz.

In embodiments with an RF power source, the RF generator may be operated at any suitable power to form a plasma of a desired composition of radical species. Examples of suitable powers include, but are not limited to, powers between about 0.5 kW and about 6 kW. Likewise, the RF generator may provide RF power of a suitable frequency, such as 13.56 MHz for an inductively-coupled plasma.

Reducing gas species 620a are delivered from a gas inlet 642a into an internal volume of the remote plasma source 640a. The power supplied to the coils 644a can generate a remote plasma with the reducing gas species 620a to form radicals of the reducing gas species 620a. The radicals formed in the remote plasma source 640a can be carried in the gas phase towards the substrate 610a through the showerhead 630a. The radicals of the reducing gas species 620a can reduce metal oxides on the surface of the substrate 610a.

In addition to radicals of the reducing gas species, the remote plasma can also include ions and other charged species of the reducing gas species 620a. In some embodiments, the remote plasma may include neutral molecules of the reducing gas species 620a. Some of the neutral molecules may be recombined molecules of charged species from the reducing gas species 620a. The neutrals or recombined molecules of the reducing gas species 620a can also reduce metal oxides on the surface of the substrate 610a, though they may take longer to react and reduce the metal oxides than the radicals of the reducing gas species 620a. The ions may drift to the surface of the substrate 610a and reduce the metal oxides, or the ions may be accelerated toward the surface of the substrate 610a to reduce the metal oxides if the substrate support 605a has an oppositely charged bias. Having species with higher ion energies can allow deeper implantation into the metal seed layer or semi-noble metal layer to create metastable radical species further from the surface of the substrate 610a. For example, if the substrate 610a has high aspect ratio features, such as between about 10:1 and about 60:1, ions with higher ionic energies may penetrate deeper into such features to provide reduction of the metal oxide more throughout the features. In contrast, some of the radicals of the reducing gas species 620a from remote plasma generation may recombine in the field or near the top of the features. The ions with higher ionic energies (such as 10 eV-100 eV) can also be used to re-sputter and reflow the metal in the metal seed layer, which can result in a more uniform seed coverage and reduce the aspect ratio for subsequent plating or metal deposition (such as PVD, CVD, ALD).

In FIG. 6A, the remote plasma apparatus 600a may actively cool or otherwise control the temperature of the substrate 610a. The remote plasma apparatus 600a can include movable members 615a, such as lift pins, that are capable of moving the substrate 610a away from or towards the substrate support 605a. The movable members 615a may contact the lower surface of the substrate 610a or otherwise pick up the substrate 610a from the substrate support 605a. In some embodiments, the movable members 615a may move the substrate 610a vertically and control the spacing between the substrate 610a and the substrate support 605a. In some embodiments, the movable members 615a can include two or more actuatable lift pins. The movable members 615a can be configured to extend between about 0 inches and about 5 inches, or more, away from the substrate support 605a. The movable members 615a can extend the substrate 610a away from a hot substrate support 605a and towards a cool showerhead 630a to cool the substrate 610a. The movable members 615a can also retract to bring the substrate 610a towards a hot substrate support 605a and away from a cool showerhead 630a to heat the substrate 610a. By positioning the substrate 610a, the temperature of the substrate 610a can be adjusted. When positioning the substrate 610a, the showerhead 630a and the substrate support 605a can be held at a constant temperature.

In some embodiments, the remote plasma apparatus 600a can include a showerhead 630a that allows for control of the showerhead temperature. In some embodiments, the temperature of the showerhead 630a may be controlled to below about 30° C., such as between about 5° C. and about 20° C. The showerhead 630a may be cooled to reduce damage to the metal seed layer that may result from excess heat during processing of the substrate 610a. The showerhead 630a may also be cooled to lower the temperature of the substrate 610a, such as before and after processing the substrate 610a.

In some embodiments, the showerhead 630a may include a plurality of holes. Increasing the size and number of holes in the showerhead 630a and/or decreasing the thickness of the showerhead 630a may permit greater flow of radicals, ions, and UV radiation from the reducing gas species 620a through the showerhead 630a. Exposing the metal seed layer to more radicals, ions, and UV radiation can provide more UV exposure and energetic species to reduce metal oxide in the metal seed layer or semi-noble metal layer. In some embodiments, the showerhead 630a can include between about 100 and about 900 holes. In some embodiments, an average diameter of the holes can be between about 0.05 and about 0.5 inches. This can result in an open area in the showerhead 630a due to holes of between about 3.7% and about 25%. In some embodiments, the showerhead 630a can have a thickness between about 0.25 and about 3.0 inches.

In some embodiments, the substrate support 605a may be configured to move to and away from the showerhead 630a. The substrate support 605a may extend vertically to control the spacing between the substrate 610a and the showerhead 630a. When reducing metal oxides on the substrate 610a, the uniformity as well as the rate of the reduction on the substrate 610a may be tuned. In some embodiments, the substrate support 605a can be configured to extend between about 0 inches and about 5 inches, or greater than about 5 inches, from the showerhead 630a.

In some embodiments, the temperature of the substrate support 605a may also be adjusted. In some embodiments, the substrate support 605a can be a pedestal with one or more fluid channels (not shown). The fluid channels may circulate a heat transfer fluid within the pedestal to actively cool or actively heat the pedestal, depending on the temperature of the heat transfer fluid. In some embodiments, the temperature of the substrate support 605a can be adjusted to be between about 0° C. and about 400° C.

In some embodiments, the remote plasma apparatus 600a can include one or more gas inlets 622a to flow cooling gas 660a through the processing chamber 650a. The one or more gas inlets 622a may be positioned above, below, and/or to the side of the substrate 610a. The flow of cooling gas 660a across the substrate 610a can enable rapid cooling of the substrate 610a. Rapid cooling of the substrate 610a can reduce the oxidation of the metal seed layer or the semi-noble metal layer in the substrate 610a. Such cooling of the substrate 610a may take place before and after processing of the substrate 610a. The flow rate of the cooling gas 660a for cooling can be between about 0.1 standard liters per minute (slm) and about 100 slm. Examples of cooling gas 660a can include a relatively inert gas, such as nitrogen, helium, neon, krypton, xenon, radon, and argon. In some embodiments, the cooling gas 660a can be delivered at room temperature, such as between about 10° C. and about 30° C. In some embodiments, the cooling gas 660a can be delivered at a temperature less than room temperature. For example, a cold inert gas may be formed by expanding a cold liquid to gas, such as liquid argon, helium, or nitrogen. Thus, the temperature range of the cooling gas 660a used for cooling can be broadened to be anywhere between about −270° C. and about 30° C.

A controller 635a may contain instructions for controlling parameters for the operation of the remote plasma apparatus 600a. The controller 635a will typically include one or more memory devices and one or more processors. The processor may include a CPU or computer, analog and/or digital input/output connections, stepper motor controller boards, etc. Aspects of the controller 635a may be further described with respect to the controller in FIGS. 5A and 5B.

An atmospheric plasma apparatus for treating a substrate prior to deposition can be disclosed. In some embodiments, the atmospheric plasma apparatus may be part of an electroplating apparatus. FIG. 6B shows an example of a cross-sectional schematic diagram of a direct atmospheric plasma apparatus. The direct atmospheric plasma apparatus 600b can include a substrate support 605b such as a pedestal for supporting a substrate 610b. The direct atmospheric plasma apparatus 600b also can include movable members 615b, such as lift pins, that are capable of moving the substrate 610b away from or towards the substrate support 605b. The direct atmospheric plasma apparatus 600b also can include a plasma distributor 640b over the substrate 610b, where the plasma distributor 640b is configured to deliver atmospheric plasma to the substrate 610b. The plasma distributor 640b can include a plurality of atmospheric plasma sources 642b. In some embodiments, the atmospheric plasma sources 642b can include plasma jets. In some embodiments, the atmospheric plasma sources 642b can include a plurality of hollow cathodes. The plurality of atmospheric plasma sources 642b may be arranged in a certain geometry to promote a more uniform distribution of atmospheric plasma across the substrate 610b.

Each of the plasma sources 642b may have gas inlets 644b for receiving a process gas. In some embodiments, the process gas can flow into a discharge section of the atmospheric plasma sources 642b, where a high voltage pulse generator 612b can excite the process gas and convert it to plasma 620b. The plasma 620b can flow from the atmospheric plasma sources 642b to the substrate 610b. In some implementations, the process gas can flow to a space between the plasma distributor 640b and the substrate 610b, where the process gas can be converted to plasma 620b by dielectric barrier discharge. Process gas can flow in a direction substantially perpendicular to the surface of the substrate 610b or substantially parallel to the surface of the substrate 610b. In some implementations, the substrate 610b can be rotated to gain a more uniform exposure. Depending on the type of atmospheric plasma source used, the electrical connections to the atmospheric plasma source can vary.

The plasma distributor 640b can include a first metal electrode and a ceramic body over the first metal electrode, where the first metal electrode is connected to a high voltage pulse generator 612b. The substrate support 605b also can be connected to the high voltage pulse generator 612b, where the substrate support 605b can include a second metal electrode. A dielectric barrier discharge can generate plasma discharge between the two metal electrodes. In some implementations, the substrate 610b can serve as the dielectric barrier. In some implementations, a dielectric-coated or ceramic-bonded metal showerhead can serve as the dielectric barrier.

The high voltage pulse generator 612b can be electrically coupled to the substrate support 605b and the plasma distributor 640b. In some implementations, the high voltage pulse generator 612b can be configured to deliver a high voltage signal between about 100 V and about 50,000 V, or between about 5,000 V and about 15,000 V, where the high voltage signal has a frequency between about 1 and about 100 kHz. In contrast to the high frequencies generated on the order of MHz in low pressure plasma apparatuses, high pressure plasma apparatuses use lower frequencies on the order of kHz. In contrast to the low voltages applied on the order of 1-100 V in low pressure plasma apparatuses, high pressure plasma apparatuses apply higher voltages on the order of kV.

The plasma 620b generated from the atmospheric plasma sources 642b may include radicals, ions, and UV radiation from the process gas. In some implementations, the plasma 620b includes radicals, ions, and UV radiation from a reducing gas species, such as hydrogen or ammonia. The plasma 620b may travel towards the substrate 610b to treat the substrate 610b prior to deposition.

The movable members 615b may position the substrate 610b at a distance from the substrate support 605b. When the substrate support 605b can be heated or cooled to a certain temperature, positioning the temperature of the substrate 610b can be controlled by positioning the substrate 610b at a certain distance from the substrate support 605b.

The movable members 615b may position the substrate 610b at a distance from the plasma distributor 640b. The density of generated plasma at the surface of the substrate 610b may be controlled by the distance of the substrate 610b from the plasma distributor 640b. It may be difficult to control the multiple reaction pathways that plasma 620b may undergo in high or atmospheric pressure, resulting in a relatively small mean free path for radicals and ions of the plasma 620b. A closer distance between the substrate 610b and the plasma distributor 640b may provide for increased radical and ion density. Thus, the position of the substrate 610b from the plasma distributor 640b can be on the order of millimeters. In some implementations, the distance between the substrate 610b and the plasma distributor 640b can be between about 0.1 mm and about 10 mm, or between about 0.1 mm and about 3 mm.

The direct atmospheric plasma apparatus 600b may include a controller (not shown) for controlling parameters for the operation of the direct atmospheric plasma apparatus 600b. Aspects of the controller may be described with respect to FIGS. 5A and 5B. In some implementations, the controller may include instructions for performing one or more operations. The operations may include providing the substrate 610b between the substrate support 605b and the atmospheric plasma sources 642b, providing a process gas to the atmospheric plasma sources 642b, forming a plasma under atmospheric pressure in the atmospheric plasma sources 642b where the plasma includes radicals and ions of the process gas, and exposing the substrate 610b to the plasma under atmospheric pressure to treat the surface of the substrate 610b. The controller may include instructions for performing additional operations discussed with respect to FIGS. 3A and 3B. For example, the controller may include instructions for providing the substrate with a metal seed layer formed thereon, a portion of the metal seed layer having been converted to oxide of the metal, and exposing the metal seed layer of the substrate to plasma under conditions that reduce the oxide of the metal and reflow the metal in the metal seed layer.

FIG. 6C shows an example of a cross-sectional schematic diagram of a remote atmospheric plasma apparatus. The remote atmospheric plasma apparatus 600c can include a substrate support 605c, a substrate 610c, one or more movable members 615c, a plasma distributor 640c, and a plurality of atmospheric plasma sources 642c as described in the direct atmospheric plasma apparatus 600b in FIG. 6B.

However, unlike the direct atmospheric plasma apparatus 600b, the remote atmospheric plasma apparatus 600c can include a showerhead 630c disposed between the plasma distributor 640c and the substrate 610c. The showerhead 630c can include a ceramic material with a plurality of holes. Increasing the size and number of holes in the showerhead 630c and/or decreasing the thickness of the showerhead 630c may permit greater flow of radicals, ions, and UV radiation through the showerhead 630c. In some implementations, the showerhead 630c can have a thickness between about 0.25 inches and about 3.0 inches, and the showerhead 630c can have between about 100 and about 2000 holes where the average diameter of the holes can be between about 0.05 inches and about 0.5 inches. The temperature of the showerhead 630c also may be controlled. In some implementations, the temperature of the showerhead 630c may be controlled to be less than about 30° C., such as between about 5° C. and about 20° C.

In some embodiments, the atmospheric plasma sources 642c may generate plasma 620c when process gas is excited and converted to plasma 620b under atmospheric pressure. For example, the atmospheric plasma sources 642c can include a plurality of plasma jets. In another example, the atmospheric plasma sources 642c can include a plurality of hollow cathodes. The atmospheric plasma sources 642c may serve as point sources for generating plasma 620c, and the plasma 620b flows from the atmospheric plasma sources 642c to the showerhead 630c. The showerhead 630c distributes radicals, ions, and UV radiation of the process gas to the substrate 610c to treat the substrate 610c. In some embodiments, the substrate can include oxide of metal and for a metal seed layer, and the plasma 620c may reduce the oxide of the metal and reflow the metal in the metal seed layer. The plasma 620c may include radicals, ions, and UV radiation from a reducing gas species, such as hydrogen or ammonia.

The movable members 615c may position the substrate 610c at a distance from the showerhead 630c. The density of generated plasma at the surface of the substrate 610c may be controlled by the distance of the substrate 610c from the showerhead 630c. In some implementations, the distance between the substrate 610c and the showerhead 630c can be between about 0.1 mm and about 10 mm, or between about 0.1 mm and about 3 mm.

In some implementations, the remote atmospheric plasma apparatus 600c may function identically or similarly as the remote plasma apparatus 600a in FIG. 6A, except that the generated plasma 620c is formed under high or atmospheric pressure, and the substrate 610c is exposed to plasma 620c under high or atmospheric pressure.

The remote atmospheric plasma apparatus 600c may include a controller (not shown) for controlling parameters for the operation of the remote atmospheric plasma apparatus 600c. Aspects of the controller may be described with respect to FIGS. 5A and 5B. In some implementations, the controller may include instructions for performing one or more operations. The operations may include providing the substrate 610c between the substrate support 605c and the atmospheric plasma sources 642c, providing a process gas to the atmospheric plasma sources 642c, forming a plasma under atmospheric pressure in the atmospheric plasma sources 642c where the plasma includes radicals and ions of the process gas, and exposing the substrate 610c to the plasma under atmospheric pressure to treat the surface of the substrate 610c. The controller may include instructions for performing additional operations discussed with respect to FIGS. 3A and 3B. For example, the controller may include instructions for providing the substrate with a metal seed layer formed thereon, a portion of the metal seed layer having been converted to oxide of the metal, and exposing the metal seed layer of the substrate to plasma under conditions that reduce the oxide of the metal and reflow the metal in the metal seed layer.

FIG. 6D shows an example of a cross-sectional schematic diagram of an atmospheric plasma apparatus using a hollow cathode discharge. The atmospheric plasma apparatus 600d can include a substrate support 605d, a substrate 610d, a high voltage pulse generator 612d, and one or more movable members 615d as described in the direct atmospheric plasma apparatus 600b in FIG. 6B.

In FIG. 6D, however, the plasma distributor 640d can include a hollow cathode, where the hollow cathode can be configured to generate a discharge of plasma 620d. The discharge of plasma 620d can be formed between two electrodes. A high voltage pulse generator 612d can be connected to each electrode, where the hollow cathode includes a first electrode and the substrate support 605d includes a second electrode. The hollow cathode may coated with metal so that the hollow cathode can serve as the first electrode. In addition or in the alternative, tips of the hollow cathode may be metal. Process gas can be received from a gas inlet 644 and flow through the plasma distributor 640d. The process gas flowing from the plasma distributor 640d can be ignited to form the plasma 620d by applying a high voltage to the plasma distributor 640d. The generated plasma 620d can include radicals, ions, and UV radiation of the process gas. The plasma 620d may include radicals, ions, and UV radiation from a reducing gas species, such as hydrogen or ammonia. The plasma 620d can diffuse toward the substrate 610d to treat the substrate 610d. In some implementations, the plasma distributor 640d can include a plurality of hollow cathodes to create multiple discharges. In some implementations, each of the plurality of hollow cathodes can include metal tips over the substrate 610d.

The atmospheric plasma apparatus 600d may include a controller (not shown) for controlling parameters for the operation of the atmospheric plasma apparatus 600d. Aspects of the controller may be described with respect to FIGS. 5A and 5B. In some implementations, the controller may include instructions for performing one or more operations. The operations may include providing the substrate 610d between the substrate support 605d and the atmospheric plasma source 642d, providing a process gas to the atmospheric plasma source 642d, forming a plasma under atmospheric pressure in the atmospheric plasma source 642d where the plasma includes radicals and ions of the process gas, and exposing the substrate 610d to the plasma under atmospheric pressure to treat the surface of the substrate 610d. The controller may include instructions for performing additional operations discussed with respect to FIGS. 3A and 3B. For example, the controller may include instructions for providing the substrate with a metal seed layer formed thereon, a portion of the metal seed layer having been converted to oxide of the metal, and exposing the metal seed layer of the substrate to plasma under conditions that reduce the oxide of the metal and reflow the metal in the metal seed layer.

Table I summarizes exemplary ranges of process parameters that can be used with any of the aforementioned embodiments of an atmospheric plasma apparatus described in FIGS. 6B-6D.

TABLE I

| Parameter | Parameter Range |
|---|---|
| Pedestal Temperature | 0° C.-400° C. |
| Showerhead Temperature | −5° C.-50° C. |
| Process Pressure | 10-760 Torr |
| Process Gas Flow (H₂/He/NH₃ - pure or mixture | 0.5 slm-30 slm |
| or CO₂/H₂ mixture) | |
| Blanket/Inert Gas Flow (N₂/He) | 10-100 slm |
| RF Plasma Voltage | 0.1-50 kV |
| RF Frequency | 1 Hz-20 MHz |
| Showerhead hole number | 100-2000 |
| Showerhead thickness | 0.25″-3.0″ |
| Showerhead hole diameter | 0.05″-0.5″ |
| Showerhead open area due to holes | 3.7%-25% |

Any of the aforementioned atmospheric plasma apparatuses may easily integrate or retrofit with other processing tools into a single unit. FIG. 7A shows an example of a cross-sectional schematic diagram of a two-chamber atmospheric plasma apparatus. Here, a pretreatment unit can combine an atmospheric plasma apparatus 750 with a transfer apparatus 700. The transfer apparatus 700 may include a heating/cooling system. For example, the transfer apparatus can include a first substrate support 705a for heating or cooling a substrate. The transfer chamber 700 may receive the substrate through an opening or port 710. The transfer chamber 700 may transfer the substrate to and from the atmospheric plasma apparatus 750, where the atmospheric plasma apparatus 750 can include a second substrate support 705b and an atmospheric plasma source 740. In some implementations, a door 720 may separate the transfer chamber 700 from the atmospheric plasma apparatus 750.

In addition, any of the aforementioned atmospheric plasma apparatuses may easily stack on top of one another to conserve space and minimize footprint. For example, a plurality of pretreatment units, such as the pretreatment units illustrated in FIG. 7A, can stack on top of one another. FIG. 7B shows an example of a cross-sectional schematic diagram of a plurality of stacked two-chamber atmospheric plasma apparatuses. In FIG. 7B, multiple transfer chambers 700a, 700b, 700c, 700d, and 700e and multiple processing chambers 750a, 750b, 750c, 750d, and 750e can stack on top of one another.

The apparatus/process described hereinabove may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically includes some or all of the following operations, each operation enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated may be performed in the sequence illustrated, in other sequences, in parallel, or in some cases omitted. Likewise, the order of the above-described processes may be changed.

### Other Embodiments

Although the foregoing has been described in some detail for purposes of clarity and understanding, it will be apparent that certain changes and modifications may be practiced within the scope of the appended claims. It should be noted that there are many alternative ways of implementing the processes, systems, and apparatus described. Accordingly, the described embodiments are to be considered as illustrative and not restrictive.

What is claimed is:

1. An apparatus for treating a substrate prior to deposition using atmospheric plasma, the apparatus comprising:
a substrate support for supporting a substrate;
a plasma distributor over the substrate support for delivering plasma to the surface of the substrate, the plasma distributor including one or more atmospheric plasma sources configured to generate the plasma; and
a controller with instructions for performing the following operations:
(a) providing the substrate between the substrate support and the plasma distributor;
(b) forming the plasma under atmospheric pressure; and
(c) exposing the substrate to the plasma under atmospheric pressure to treat the surface of the substrate, wherein atmospheric pressure is between about 50 Torr and about 760 Torr.

2. The apparatus of claim 1, wherein the substrate support and the plasma distributor are configured to provide the substrate at a distance of between about 0.1 mm and about 10 mm from the plasma distributor during operations (a)-(c).

3. The apparatus of claim 1, further comprising a pulse generator coupled to the one or more plasma sources.

4. The apparatus of claim 1, wherein operation (a) comprises providing the substrate with a metal seed layer formed thereon, a portion of the metal seed layer having been converted to oxide of the metal, and wherein operation (c) comprises exposing the metal seed layer of the substrate to the plasma under conditions that reduce the oxide of the metal and reflow the metal in the metal seed layer.

5. The apparatus of claim 1, wherein the metal seed layer includes a copper seed layer having a thickness between about 40 Å and about 80 Å.

6. The apparatus of claim 1, wherein the controller further comprises instructions for:
after exposing the substrate to the plasma, transferring the substrate to a plating bath containing a plating solution.

7. The apparatus of claim 6, wherein the apparatus is configured for transferring the substrate occurs under atmospheric pressure and temperature.

8. The apparatus of claim 1, wherein the apparatus is configured to form the plasma at a temperature of less than about 75° C.

9. The apparatus of claim 1, further comprising a processing chamber, wherein the apparatus is configured to perform operations (b) and (c) within the processing chamber.

10. The apparatus of claim 1, where the one or more plasma sources include a plurality of plasma jets.

11. The apparatus of claim 1, wherein the one or more plasma sources are configured to form a dielectric barrier discharge.

12. The apparatus of claim 1, wherein the one or more plasma sources include a plurality of hollow cathodes.

13. The apparatus of claim 1, wherein the apparatus is configured to produce the plasma from a forming gas, the forming gas including hydrogen and nitrogen gas.

14. The apparatus of claim 1, wherein the controller further comprises instructions for:
before exposing the substrate to the plasma, delivering a blanket of inert gas between the plasma distributor and the substrate.

15. The apparatus of claim 1, wherein the apparatus is configured such that the plasma includes radicals and ions of a reducing gas species including at least one of hydrogen and ammonia.

16. The apparatus of claim 1, wherein the plasma distributor comprises a ceramic body and a metal electrode below the ceramic body.

17. The apparatus of claim 1, further comprising a showerhead disposed between the plasma distributor and the substrate, the showerhead including a plurality of holes.

18. A method of treating a substrate prior to deposition with an atmospheric plasma, the method comprising:
providing a substrate between a substrate support and one or more atmospheric plasma sources;
providing a process gas to the one or more atmospheric plasma sources;
forming a plasma under atmospheric pressure in the one or more atmospheric plasma sources, the plasma including radicals and ions of the process gas; and
exposing the substrate to the plasma under atmospheric pressure to treat the surface of the surface of the substrate, wherein atmospheric pressure is between about 50 Torr and about 760 Torr.

19. The method of claim 18, wherein providing the substrate comprises providing the substrate at a distance of between about 0.1 mm and about 10 mm below the one or more atmospheric plasma sources.

20. The method of claim 18, wherein providing the substrate comprises providing the substrate with a metal seed layer formed thereon, a portion of the metal seed layer having been converted to oxide of the metal, and wherein exposing the substrate to the plasma comprises exposing the metal seed layer of the substrate to the plasma under conditions that reduce the oxide of the metal and reflows the metal in the metal seed layer.

21. The method of claim 18, wherein forming the plasma includes forming the plasma at a temperature of less than about 75° C.

22. The method of claim 18, further comprising:
after exposing the substrate to the plasma, transferring the substrate to a plating bath containing a plating solution.

23. The method of claim 18, wherein the plasma includes radicals and ions of a reducing gas species including at least one of hydrogen and ammonia.

24. The method of claim 18, further comprising:
applying a pulse of greater than about 5,000 V to the one or more atmospheric plasma sources to form the plasma.
